(19) United States
(12) Patent Application Publication
(10) Pub. No.: US 2014/0063943 A1
(43) Pub. Date: Mar. 6, 2014

(54) MEMORY SYSTEM AND CONTROL METHOD THEREOF

(71) Applicant: KABUSHIKI KAISHA TOSHIBA, Tokyo (JP)

(72) Inventor: Hiroyuki NAGASHIMA, Yokohama-shi (JP)

(21) Appl. No.: 14/018,197

(22) Filed: Sep. 4, 2013

(30) Foreign Application Priority Data
Sep. 4, 2012 (JP) 2012-194157

(51) Int. Cl. G11C 16/30

(52) U.S. Cl. CPC G11C 16/30
USPC 365/185.08; 365/185.23

(57) ABSTRACT

According to one embodiment, a memory system includes a semiconductor memory including a memory core having first and second circuits and an input/output circuit, a control device, a voltage control circuit which generates first to third drive voltages, and the first to third power supply lines separated from each other. The voltage control circuit supplies the first drive voltage to the first circuit through the first power supply line, the second drive voltage lower than the first drive voltage to the input/output circuit and the control device through the second power supply line, and the third drive voltage to the second circuit through the third power supply line.

### CROSS-REFERENCE TO RELATED APPLICATIONS

This application is based upon and claims the benefit of priority from Japanese Patent Application No. 2012-194157, filed Sep. 4, 2012, the entire contents of which are incorporated herein by reference.

### FIELD

Embodiments described herein relate generally to a memory system and a memory system control method.

### BACKGROUND

In recent years, along with an HDD, a CD/DVC, and the like, a flash memory has been used in various electronic devices as a primary storage device.

For example, a reduction in power consumption has been demanded for a memory system (memory device) using the flash memory.

### BRIEF DESCRIPTION OF THE DRAWINGS

FIG. 1 is a block diagram showing a basic example of a memory system according to this embodiment;

FIG. 2 is a block diagram showing a configuration example of the memory system according to this embodiment;

FIG. 3 is a view showing a configuration example of a semiconductor memory included in the memory system;

FIG. 4 is a block diagram showing a configuration example of a semiconductor memory included in the memory system;

FIG. 5 is an equivalent circuit diagram showing an internal configuration of a memory cell array;

FIG. 6 is a schematic cross-sectional view showing the structural example of the semiconductor memory according to this embodiment;

FIG. 7 is a block diagram showing a configuration example of a memory system according to this embodiment;

FIG. 8 is a flow chart showing an operation example of a memory system and a semiconductor memory according to this embodiment;

FIG. 9 is a block diagram showing a configuration example of a memory system according to this embodiment; and

FIG. 10 is schematic view showing an configuration example of the semiconductor memory according to this embodiment.

### DETAILED DESCRIPTION

### Embodiment

This embodiment will now be described hereinafter with reference to the drawings. In the following explanation, like reference numerals denote elements having the same functions and structures, and an overlapping description will be given as required.

In general, according to one embodiment, a memory system includes a first semiconductor memory includes: a first semiconductor memory including: a memory core; an input/output circuit configured to input/output a signal; and first to third power supply terminals which are electrically separated from each other, the memory core including a memory cell array including memory cells; a first circuit configured to generate a voltage supplied to the memory cell array; and a second circuit configured to control an operation of the memory cell array, the first power supply terminal being connected to the first circuit, the second power supply terminal being connected to the input/output circuit, and the third power supply terminal being connected to the second circuit; a control device which controls an operation of the first semiconductor memory; a voltage control circuit to which a reference voltage and a first voltage higher than the reference voltage is input and which generates first to third drive voltages higher than the reference voltage from the first voltage; and first to third power supply lines that are electrically separated from each other, the first power supply line being connected to the first power supply terminal, the second power supply line being connected to the second power supply terminal and the control device, and the third power supply line being connected to the third power supply terminal, wherein the voltage control circuit supplies: the first drive voltage to the first circuit through the first power supply terminal and the first power supply line, the second drive voltage lower than the first drive voltage to the input/output circuit through the second power supply terminal and the second power supply line; the third drive voltage to the second circuit through the third power supply terminal and the third power supply line; and the second drive voltage to the control device through the second power supply line.

(1) Basic Example

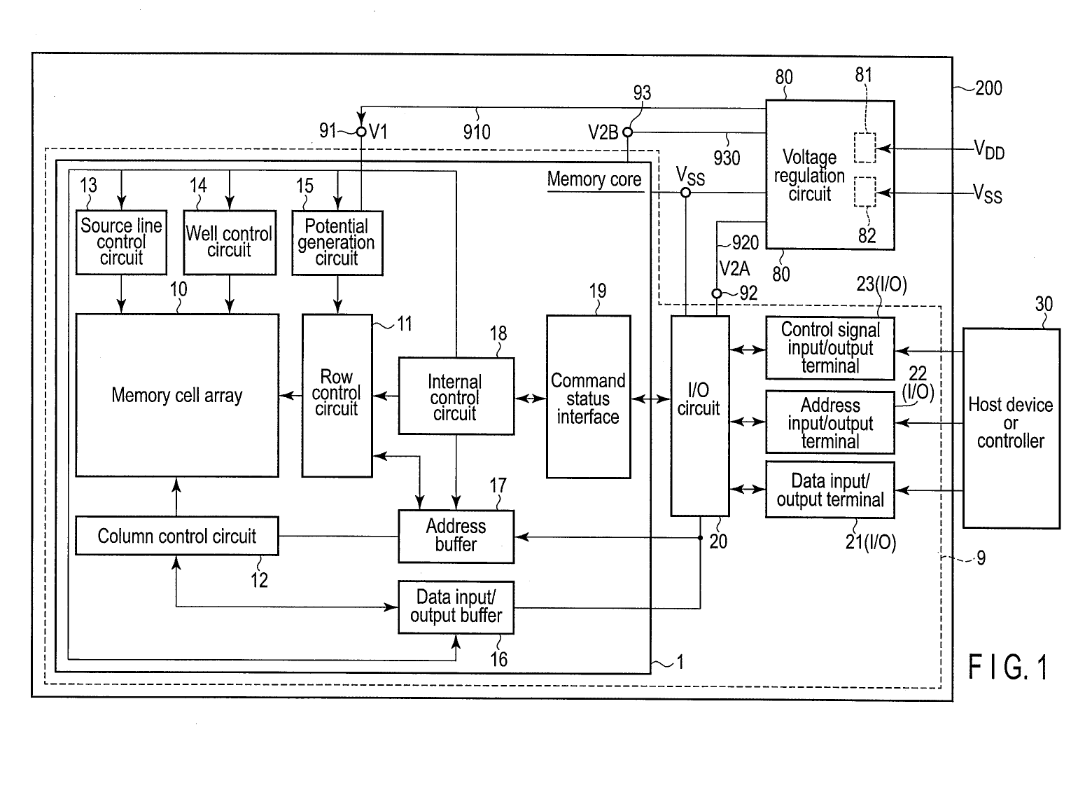

A configuration and a function of a memory system according to a basic example in this embodiment will now be described with reference to FIG. 1.

FIG. 1 is a block diagram showing a primary part of a configuration of a memory system according to this embodiment.

The memory system according to this embodiment includes, e.g., a nonvolatile semiconductor memory 9 and a voltage regulation circuit (voltage control circuit) 80. For example, the nonvolatile semiconductor memory is a flash memory.

In the flash memory 9, a memory cell array 10 includes memory cells.

A row control circuit 11 controls rows in the memory cell array 10. The row control circuit 11 is connected to the word lines and select gate lines provided in the memory cell array 10. The row control circuit 11 selects a control unit set to the rows in the memory cell array 10 based on a row address transferred from an address buffer 17 and controls operations (potentials) in the word line and the select gate lines.

A column control circuit 12 controls columns in the memory cell array 10. The column control circuit 12 selects a control unit set to the columns in the memory cell array 10 based on a column address transferred from the address buffer 17 and controls operations (potentials) of the bit lines.

A source line control circuit 13 controls a potential in the source line connected to the memory cell units MU.

A well control circuit 14 controls a potential in a well region in the memory cell array 10.

A potential generation circuit 15 generates a write voltage, a read voltage, an intermediate voltage, and a non-selection potential that are applied to the respective word lines at the time of writing (programming) data, reading data, and erasing data, respectively. The potential generation circuit 15 generates potentials that are applied to, e.g., the select gate lines. The potentials generated by the potential generation circuit 15 are transferred to the row control circuit 11 and applied to the selected/non-selected word lines and the select gate lines, respectively.

Further, the potential generation circuit 15 generates a potential that is applied to the source line and a potential that is applied to the well region. The potential generation circuit 15 transfers the generated potentials to the source line control circuit 13 and the well control circuit 14.

A data input/output buffer 16 serves as a data input/output interface. The data input/output buffer 16 temporarily holds data from an external device (e.g., a host device or a controller) 30 input through a data input/output terminal 21 as an input/output terminal (an I/O terminal). The data input/output buffer 16 temporarily holds data output from the memory cell array 10 and outputs the held data to the outside of the flash memory 9 through the data input/output terminal 21 at a predetermined timing.

The address buffer 17 temporarily holds an address signal input through an address input/output terminal 22 as an I/O terminal. The address signal from the outside is, e.g., a physical address, and it includes a physical row address and a physical column address.

An internal control circuit 18 manages an operation of the entire flash memory 9. The internal control circuit 18 receives a control signal (a command) input from a control signal input/output terminal 23 as an I/O terminal. The internal control circuit 18 transmits a control signal (a status) indicative of an operation status in the flash memory 9 to an external device 30 through the control signal input/output terminal 23. A command or a status as the control signal is input to or output from the internal control circuit 18 through a command/status interface 19.

An internal configuration of the chip of flash memory 9 including the circuits 11 to 19, e.g., the memory cell array 10, the row/column control circuits 11 and 12, and the internal control circuit 18 will be referred to as a memory core (or an NAND core) 1 hereinafter.

The host device 30 or the controller 30 is provided outside the chip of the flash memory 9. The host device 30 or the controller 30 transmits the control signal (a command) to the flash memory 9 and instructs the flash memory 9 to write data into or read data from each memory cell. The host device 30 or the controller 30 receives the control signal (a status) from the flash memory 9 and grasps an operating status of the flash memory 9.

Furthermore, the host device 30 or the controller 30 transmits data to be written and an address indicative of a row and a column where data is to be written together with a command to the flash memory 9. The host device 30 or the controller 30 receives data read from the flash memory 9 in response to a command. Moreover, the host device 30 or the controller 30 receives an address associated with the read data. The controller 30 may be provided in the memory system 200.

An input/output control circuit (which will be also referred to as an I/O circuit hereinafter) 20 is provided between a memory core 1 and the host device 30 or the controller 30. The I/O circuit 20 is provided in, e.g., the same chip (a semiconductor substrate) as the memory core 1.

The I/O circuit 20 includes, e.g., a control unit (an interface processing unit) configured to execute interface processing. The I/O circuit 20 controls an operation timing of data input/out, command reception, status transmission, and others between the memory core 1 and the external device 30 of the memory core 1.

The I/O circuit 20 is connected to the host device 30 or the controller 30 through, e.g., the I/O terminals 21, 22, and 23 and I/O signal lines. The I/O circuit 20 is connected to the circuits 16, 17, and 18 in the memory core 1 directly or through an interface circuit, e.g., the command/status interface 19.

In this embodiment, the circuits 11 to 20 in the chip other than the memory cell array 10 are called peripheral circuits.

A voltage regulation circuit 80 configured to apply a predetermined voltage to the inside of the flash memory is connected to the flash memory 9. The voltage regulation circuit 80 is provided outside the chip of the flash memory 9. A package including the voltage regulation circuit 80 is provided on a same circuit substrate as a package including the flash memory 9.

The voltage regulation circuit 80 directly supplies voltages (which will be also referred to as external power supply voltages hereinafter) V_{DD} and V_{SS} from the outside of the memory system 200 or supplies voltages obtained by boosting or reducing the external power supply voltages V_{DD} and V_{SS} to the circuits 10 to 20 in the chip of the flash memory 9. When the voltages from the voltage regulation circuit 80 are supplied, the internal circuits 10 to 20 of the flash memory 9 are driven. In this embodiment, voltages V1, V2A, V2B and V_{SS} supplied to the circuits 10 to 20 in the flash memory 9 from the voltage regulation circuit 80 are also referred to as drive voltages.

The voltage regulation circuit 80 has at least two terminals 81 and 82 connected to the external power supplies V_{DD} and V_{SS} of the memory system 200. In this embodiment, the power supply terminals 81 and 82 in the voltage regulation circuit 80 which are connected to the external power supplies V_{DD} and V_{SS} are called power supplies in some cases.

The voltage regulation circuit 80 outputs three or more drive voltages V_{SS}, V1, V2A, and V2B having different intensities to the circuits 10 to 20 in the flash memory 9.

In the three or more drive voltages output to the circuits 10 to 20 in the flash memory 9 from the voltage regulation circuit 80, one drive voltage V_{SS} is a ground voltage V_{SS}. The ground voltage V_{SS} is supplied to the respective circuits 10 to 20 in the flash memory 9 in common through interconnects (power supply lines). To distinguish from drive voltages higher than the ground voltage, the ground voltage V_{SS} may be referred to as a reference voltage (or a reference potential) in some cases.

In the three or more drive voltages output to the circuits 10 to 20 in the flash memory 9 from the voltage regulation circuit 80, the drive voltages V1, V2A, and V2B excluding the ground voltage V_{SS} are voltages having values (absolute values) higher than the ground voltage V_{SS}. Each of the drive voltages V1, V2A, and V2B has, e.g., a voltage value that is not greater than the voltage V_{DD} by the control of the voltage regulation circuit 80.

However, the voltage regulation circuit 80 may boost the voltage V_{DD} and supply each drive voltage higher than the voltage V_{DD} to the flash memory 9 in some cases.

The first voltage V1 as the drive voltage is supplied to a certain circuit region (e.g., the potential generation circuit 15) in the memory core 1 from the voltage regulation circuit 80 through a terminal (a pad) 91 and a power supply line (a voltage line) 910. The drive voltage V2A lower than the drive voltage V1 supplied to the memory core 1 is supplied to the I/O circuit 20 from the voltage regulation circuit 80 through a terminal 92 and a power supply line 920 as the drive voltage. Further, the drive voltage V2B is supplied to the other circuit region (e.g., the internal control circuit 18) which is part of the inside of the memory core 1 through a terminal 93 and a power supply line 930. The drive voltage V2B is appropriately set to, e.g., an intensity that falls within the range from the drive voltage V1 to the drive voltage V2A in accordance with the specifications of the memory system 200.

The terminals 91, 92, and 93 and the power supply lines 910, 920, and 930 configured to supply the respective drive voltages V1, V2A, and V2B to the inside of the flash memory 9 are electrically separated from each other. As a result, in the memory system 200 and the flash memory 9, an independent power supply system is formed in accordance with each of the drive voltages V1, V2, and V2B. As a result, compatibility of the external power supply voltages and the drive voltages supplied to the memory system 200 and the flash memory 9 in the memory system 200 is improved.

In the flash memory 9, the relatively high drive voltage V1 is used as a write voltage or a read voltage for the memory cell MC at the time of an operation of the memory core 1.

On the other hand, the I/O circuit 20 can be driven with the drive voltage V2A lower than the drive voltage V1 of the memory core 1.

Like the flash memory 9 according to this embodiment, when the drive voltage V2A lower than the drive voltage V1 for the memory core 1 is supplied to the I/O circuit 20, a power consumption of the flash memory 9 can be reduced as compared with an example where the same drive voltage is supplied to the memory core 1 and the I/O circuit 20. Furthermore, when the drive voltage V1 higher than the voltage V2A supplied to the I/O circuit 20 is supplied to the memory core 1, it is possible to suppress deterioration in operation characteristics of the memory core 1 due to a reduction in voltage that occurs when an application voltage of the entire chip is decreased.

As described above, according to the memory system of this embodiment, the power consumption of the memory can be reduced.

(2) Configuration Example

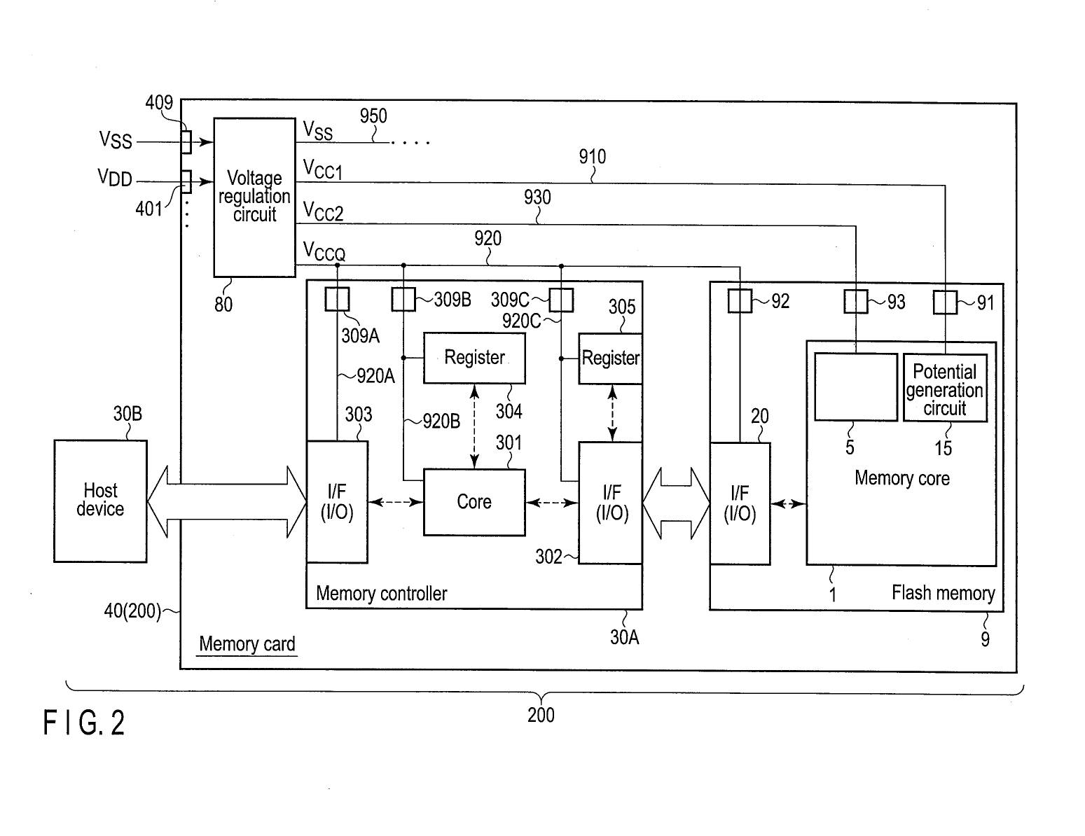

A configuration example of the memory system according to this embodiment will now be described with reference to FIG. 2 to FIG. 10.

The memory system according to this embodiment is a system using a flash memory, for example, a memory device such as a solid state drive (SSD) or a memory card conforming to the embedded multi media card (eMMC) standard, the mini serial advanced technology attachment (mSATA) standard, or the universal flash storage (UFS) standard.

For example, in this embodiment, when the flash memory 9 is mounted on the same circuit substrate (a print substrate, a mount substrate, or a mother board) together with a controller for the flash memory 9, a memory system 200 using the flash memory 9 according to this embodiment can be formed.

A memory card and an SSD will be exemplified and a configuration example of the memory system according to this embodiment will now be described hereinafter.

(a) Memory Card

A memory card as the memory system according to this embodiment will now be described with reference to FIG. 2 to FIG. 8.

FIG. 2 shows an internal configuration example of a memory card 40 as one example of the memory system 200 according to this embodiment.

As shown in FIG. 2, the memory card 40 includes the flash memory 9, a memory controller (a card controller) 30A, a voltage regulation circuit 80, and connectors 401 and 409. The memory card 40 is configured to be inserted into or removed from a slot provided in a host device 30 or an external device (e.g., a PC, a mobile terminal, or a digital camera) including the host device 30B.

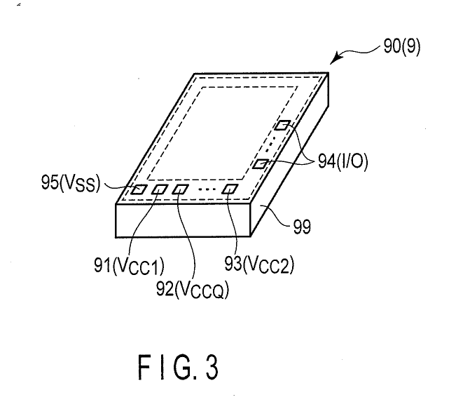

A configuration example of a flash memory 9 in the memory card 40 as the memory system according to this embodiment will now be described with reference to FIG. 3 to FIG. 6.

FIG. 3 shows a configuration example of the flash memory 9.

The chip 90 of the flash memory 9 is covered with, e.g., an insulator (a package material) 99. The chips 90 may be provided in one package to form a memory package (a memory module). The memory package in which the chips 90 are provided is referred to as a Multi chip package (an MCP).

Pads 91, 92, 93, and 94 connected to the interconnects inside the flash memory 9 are provided on a surface of the chip 90. The pads 91, 92, 93, 94, and 95 are the data or address input/output or voltage application terminals 21, 22, 23, 91, 92, and 93 as described above.

As the data or address input/output terminals 21, 22, and 23, the I/O pads 94 are provided on the chip 90.

To reduce the power consumption of the flash memory, a drive voltage of a part of internal circuits of the flash memory used to the memory system according to this embodiment can be commonalized with a drive voltage of a circuit (e.g., the controller) other than the flash memory in the memory system 200.

In this embodiment, to apply drive voltages V_{CC1}, V_{CC2}, V_{CCQ}, and V_{SS} having different intensities to the flash memory 9, the voltage application power supply pads (the power supply terminals) 91, 92, 93, and 95 are provided on the chip 90 of the flash memory 9 in association with the respective drive voltages V_{CC1}, V_{CC2}, V_{CCQ}, and V_{SS}.

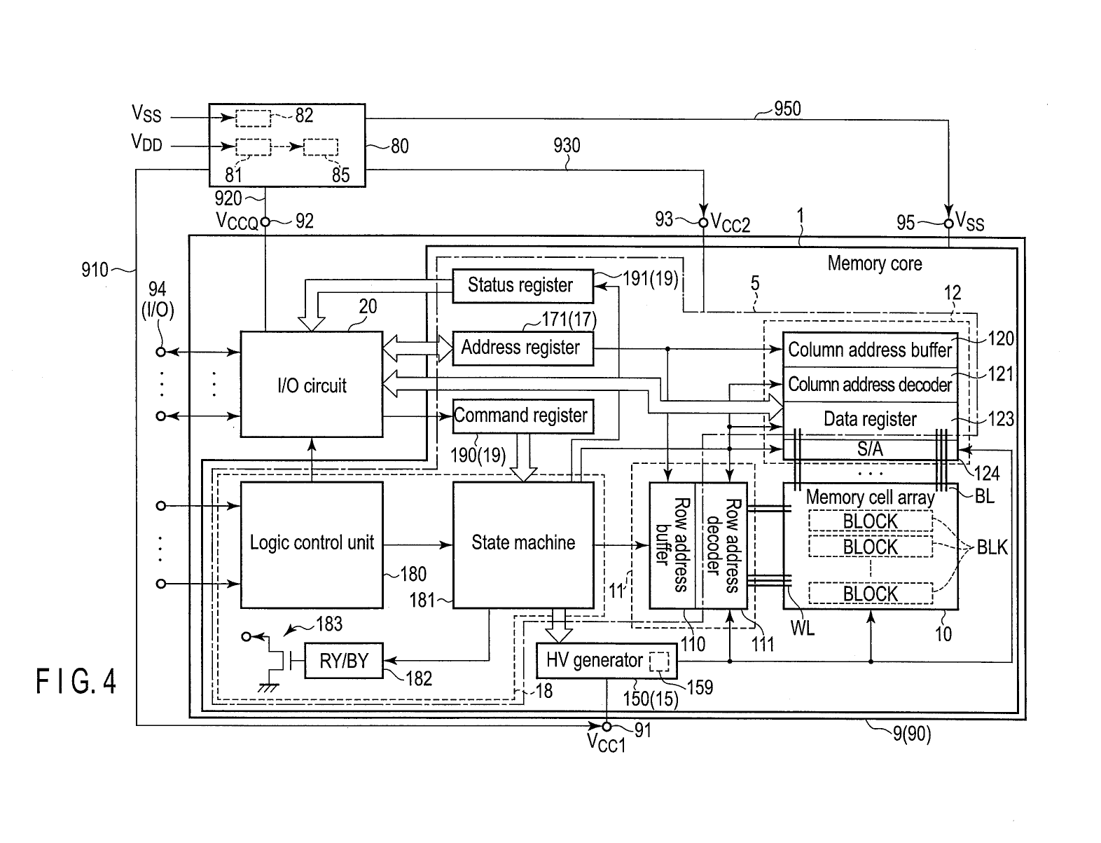

FIG. 4 is a block diagram showing an example of a circuit configuration of the flash memory 9. Here, a circuit configuration example of the flash memory 9 will be more specifically explained by appropriately using FIG. 1 in addition to FIG. 4. It is to be noted that the configurations of the source line control circuit 13 and the well control circuit 14 in FIG. 1 are omitted in FIG. 4.

If the flash memory depicted in FIG. 4 is, e.g., an NAND flash memory, the memory cell array 1 has the blocks BLK. Each of the blocks BLK represents, e.g., a minimum unit for erasing.

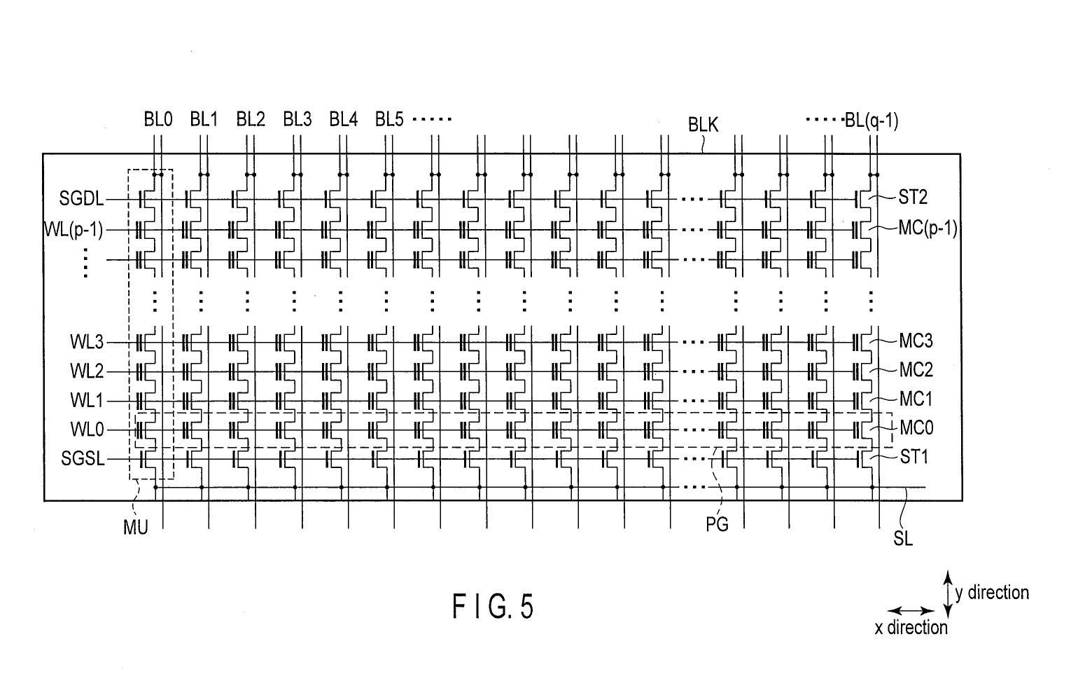

FIG. 5 is an equivalent circuit diagram showing a circuit configuration of one block BLK. One block BLK is constituted of memory cell units MU aligned in an x direction (a first direction, a row direction). In one block BLK, q (e.g., 8512) memory cell units MU are provided.

One memory cell unit MU includes a memory cell string formed of multiple (for example, p) memory cells MC0 to MC(p−1), a first select transistor ST1 connected to one end of the memory cell string (which will be referred to as a source side select transistor hereinafter), and a second select transistor ST2 connected to the other end of the memory cell string (which will be referred to as a drain side select transistor hereinafter). In the memory cell string, current paths of the memory cells MC0 to MC(p−1) are connected in series along a y direction (a second direction, a column direction).

A source line SL is connected to one end (the source side) of the memory cell unit MU, which is more specifically one end of the current path of the source side select transistor ST1. Furthermore, a bit line BL is connected to the other end (the drain side) of the memory cell unit MU, i.e., one end of the current path of the drain side select transistor ST2.

In the NAND flash memory, the number of memory cells that constitute one memory cell unit MU has only to be two or more, and may be, for example, 16, 32, or 64 or more. Hereinafter, the memory cells MC0 to MC(p−1) are represented by memory cells MC when not distinguished from one another. The source side and drain side select transistors ST1 and ST2 are represented by select transistor ST when not distinguished from one another.

The memory cell MC is a field effect transistor having a charge storage layer (e.g. a floating gate electrode, or an insulating film including a trap level). The source/drain of two memory cells MC adjacent in the y-direction are connected to each other. Thus, the current paths of the memory cells MC are connected in series, and the memory cell string is formed.

The drain of the source-side select transistor ST1 is connected to the source of the memory cell MC0. The source of the source-side select transistor ST1 is connected to the source line SL.

The source of the drain-side select transistor STD is connected to the drain of the memory cell MC(p−1). The drain of the drain-side select transistor STD is connected to one of a plurality of bit lines BL0 to BL(q−1). The number of bit lines BL1 to BLq is the same as the number of the memory cell units MU in the block BLK.

Word lines WL0 to WL(p−1) extend in the x direction, and the respective word lines WL0 to WL(p−1) are connected in common to gates of the memory cells MC aligned along the x direction. In one memory cell unit MU, the number of the word lines is the same as the number of the memory cells constituting one memory cell string.

A source side select gate line SGSL extends in the x direction and is connected in common to gates of the source side select transistors ST1 aligned along the x direction. A drain side select gate line SGDL extends in the x direction and is connected in common to gates of the drain side select transistors ST2 aligned along the x direction.

Hereinafter, bit lines BL0 to BL(q−1) are represented by bit lines BL when not distinguished from one another, and word lines WL0 to WL(p−1) are represented by word lines WL when not distinguished from one another.

Each of the memory cells MC stores external data by associating the intensity of a threshold voltage of the transistor (the distribution of the threshold voltage) with the data.

Each memory cell MC stores two-level (1 bit) data, three-level (2 bit) data, or more.

For example, when one memory cell MC stores two-level (1-bit) data “0” and “1”, the memory cell MC has two threshold distributions corresponding to these data. When one memory cell MC stores four-level (2-bit) data, “00”, “01”, “10”, and “11”, the memory cell MC has four threshold distributions corresponding to these data. A memory cell in which data having three or more levels is stored is also referred to as a multi-level memory.

Data is collectively written into and read from the memory cells MC connected to the same word line WL. A control unit of rows of the memory cell array 1 in data writing/reading is referred to as a page PG.

Data is written into and read from the multi-level memory per lower bit or per upper bit. Therefore, when the memory cell stores MC 2-bit data, two pages are allocated to one word line WL. A page collectively written or read per lower bit is referred to as a lower page. A page collectively written or read per upper bit is referred to as an upper page. A lower bit belonging to one page is referred to as lower data. An upper bit belonging to one page is referred to as upper data.

For example, in the bit lines BL, data writing or data reading can be independently executed with respect to each even-numbered bit line and an odd-numbered bit line. In the multiple (e.g., 8512) memory cells MC connected to one word line WL, data writing or data reading is simultaneously carried out with respect to the multiple (e.g., 4256) memory cells connected to the even-numbered bit lines. In this case, a data group formed of 1 bit of each of the 4256 memory cells (i.e., 4256-bit data) realizes processing as 1 page PG. In a case where one memory cell stores 2-bit data, the 4256 memory cells MC which are connected to one word line and also connected to the even-numbered bit lines store data corresponding to 2 pages. The multiple (4256) memory cells MC which are connected to one word line and also connected to the odd-numbered bit lines form 2 pages different from those of the memory cells connected to the even-numbered bit lines. Data is written or data is read at the same time to or from the memory cells within pages formed by the even-numbered bit lines. When the even-numbered or odd-numbered bit lines are independently controlled and one memory cell stores 2-bit data, 4 pages are assigned to one word line WL.

As shown in FIG. 4, the row control circuit 11 is provided in the chip 90 to be adjacent to the row side of the memory cell array 10. The row control circuit 11 includes a row address buffer 110 and a row address decoder 111.

The row address buffer 110 holds a row address from the outside and outputs it to the row address decoder 111 at predetermined timing.

The row address decoder 111 decodes a row address and selects a block and a page indicated by the row address. The row address decoder 111 activates a word line that has been selected (which will be referred to as a selected word line) WL and controls a potential in the selected word line. Furthermore, the row address decoder 111 controls a potential in each word line (which will be referred to as a non-selected word line) other than the selected word line in accordance with an operation for the selected word line.

As shown in FIG. 4, the column control circuit 12 is provided in the chip 90 to be adjacent to the column side of the memory cell array 10.

The column control circuit 12 includes a column address buffer 120, a column address decoder 121, a data register 123, and a sense amplifier circuit 124.

The column address buffer 120 holds a column address from the outside and outputs it to the column address decoder 121 at a predetermined timing.

The column address decoder 121 decodes the column address from the column address buffer 120 and activates a bit line that has been selected (which will be referred to as a selected bit line) or a control unit (which will be referred to as a column unit or a column block hereinafter) associated with the bit lines BL assigned to column in the memory cell array 10. As a result, a potential in the selected bit line and the control unit including this bit line is controlled. Moreover, the column address decoder 121 controls a potential in each bit line (which will be referred to as a non-selected bit line) other than the selected bit line in accordance with an operation for the selected bit line.

The data register 123 temporarily holds data from the outside and data from the memory cell array 10. For example, the data register 123 includes latches provided in association with the bit lines BL and these latches are activated in association with the selected bit line BL (or the column control unit).

The data register 123 may be included in the data input/output buffer 16 shown in FIG. 1. It is to be noted that, when the data register 123 in the column control circuit 12 functions as a data input/output buffer, the data input/output buffer 16 in FIG. 1 may not be provided.

The sense amplifier circuit 124 amplifies and detects a fluctuation in potential in each bit line BL indicated by a column address. For example, the sense amplifier circuit 124 includes sense units provided in association with the bit lines BL, and these sense units are activated in association with the selected bit line BL.

An address register 171 is provided in, e.g., the address buffer 17 in FIG. 1. The address register 171 holds addresses from the outside (physical addresses). The addresses held by the address register 171 are transferred to the row address buffer 110 and the column address buffer 120 as row and column addresses at a predetermined timing. The address register 171 may form the address buffer 17 in FIG. 1 together with the row address buffer 110 and the column address buffer 120. Although FIG. 4 shows the row and column address buffers 110 and 120 as internal structures of the row and column control circuits 11 and 12, these buffers may be provided outside the row and column control circuits 11 and 12 as internal structures of the address buffer 17 in FIG. 1.

A command register 190 and a status register 191 are included in the command/status interface 19 in FIG. 1.

The command register 190 temporarily holds a command from the outside and outputs the held command to the internal control circuit 18 at a predetermined timing.

The status register 191 temporarily holds a status from the internal control circuit 18 and outputs the held status to the I/O circuit 20 at predetermined timing.

The internal control circuit 18 includes a logic control unit 180, a state machine 181, a ready/busy judgment unit 182, a control element 183, and others.

The logic control unit 180 receives a control signal (e.g., an enable signal) such as Command Latch Enable (CLE) or Address Latch Enable (ALE) from the outside (the host device or the controller), and transfers it to the state machine 181. The logic control unit 180 outputs each received signal (a command or data) to the I/O circuit 20.

The state machine 181 receives a command from the command register 190 and a control signal from the logic control unit 180. To execute an operation requested from the outside, the state machine 181 drives the respective constituent units 120, 121, 123, and 124 included in the column control circuit 12, the constituent units 110 and 111 included in the row control circuit 10, and a constituent unit 150 included in the potential generation circuit 15.

Further, the state machine 181 generates a status in the flash memory 9 based on an operating status of each of the row control circuit 11, the column control circuit 12, and the potential generation circuit 15 and outputs this status to the status register 191.

The ready/busy judgment circuit 182 outputs, e.g., a control signal of an “H” or “L” level to the control element 183 based on a signal from the state machine 181. The control element 183 is, e.g., a field effect transistor 183. A signal from the ready/busy judgment unit 182 is output to a gate of the transistor 183. When the transistor 183 is turned on or off in accordance with a level of the signal applied to the gate of the transistor 183, a potential level in a source/drain of the transistor 183 fluctuates. This potential level is detected as a ready/busy signal, and the host device 30 or the controller 30 in FIG. 1 recognizes whether an operating status in the flash memory 9 is a ready state or a busy state.

The potential generation circuit 15 includes a high-voltage generator 150. The high-voltage generator 150 boosts the drive voltage V_{CC1} from the power supply voltage 80 and generates a voltage that is approximately 10 V to 20 V. This boosted voltage is applied to the selected/non-selected word line WL through the row address decoder 111 as a write voltage, a read voltage, or a non-selected potential at the time of writing or reading. Moreover, the high-potential generator 150 generates a voltage that is equal to or above the drive voltage V_{CC1} and less than 10 V and outputs it to, e.g., the sense amplifier circuit 124 in the column control circuit 12. The potential generation circuit 15 and the high-potential generator 150 include a charge pump 159 configured to boost the applied voltage.

The I/O circuit 20 has I/O terminals (I/O pads) 94.

The I/O circuit 20 transfers data (write data) input from the outside through the I/O terminals 94 to the data register 123 of the column control circuit 12. Additionally, data from the memory cell array 10 that is held in the data register 123 is output to the outside of the chip 90 through the I/O terminals 94.

The I/O circuit 20 transfers an address input from the outside through the I/O terminals 94 to the row address buffer 110 and the column address buffer 120.

The I/O circuit 20 transfers a command input from the outside through the I/O terminals 94 or input from the logic control unit 180 to the command register 190.

The I/O circuit 20 outputs a status from the status register 191 and a signal from the logic control unit 180 of the internal control circuit 18 to the outside of the chip through the I/O terminals 94.

The drive voltage V_{CC1} is supplied to the potential generation circuit 15, which is more specifically the high-voltage generator 150 in the potential generation circuit 15 in the memory core 1.

A drive voltage V_{CCQ} smaller than the drive voltage V_{CC1} supplied to the potential generation circuit 15 (the high-voltage generator 150) of the memory core 1 is supplied to the I/O circuit 20 from the voltage regulation circuit 80.

For example, in the memory core 1, a drive voltage V_{CC2} that is smaller than the drive voltage V_{CC1} is supplied to a predetermined circuit (e.g., the internal control circuit 18) other than the potential generation circuit 15. For example, the drive voltage V_{CC2} is not lower than the drive voltage V_{CCQ}.

In the following description, at least one circuit that is driven with the voltage V_{CC2} that is smaller than the drive voltage V_{CC1} supplied to the potential generation circuit 15 will be referred to as a low-voltage drive circuit group 5. For example, at least one of the internal configurations 180 to 183 in the internal control circuit 18, the buffers 110 and 120 in the row/column control circuits 11 and 12, the decoder 121, and the respective registers 123, 171, 190, and 191 in the memory core 1 belongs to the low-voltage derive circuit group 5.

On the other hand, like the potential generation circuit 15, at least one that is driven with the drive voltage V_{CC1} will be referred to as a high-voltage drive circuit group. For example, a circuit that is driven with a voltage boosted by the potential generation circuit 15 is also included in the high-voltage drive circuit group. Besides the potential generation circuit 15, for example, the address decoder 111 in the row control circuit 11 or the sense amplifier circuit 124 in the column control circuit 12 may be included in the high-voltage drive circuit group in some cases.

The ground voltage V_{SS} is supplied to the high-voltage drive circuit group 15 and the low-voltage drive circuit group 5 in the memory core 1 and the I/O circuit 20 in common through the pads 95, a power supply line (a ground line) 950, and the voltage regulation circuit 80. However, each power supply line (a ground line) electrically separated from each other may be provided to the memory core 1 and the I/O circuit 20, and the ground voltage V_{SS} may be supplied to the memory core 1 and the I/O circuit 20 from different ground lines 950.

When the internal circuits 10 to 19 in the memory core 1 are driven by using the different drive voltages V_{CC1} and V_{CC2}, to supply the drive voltage V_{CC2} different from that of the potential generation circuit 15 in the high-voltage drive circuit group to a circuit in the low-voltage drive circuit group 5, two power supply pads 91 and 93 for voltage V_{CC1} and V_{CC2} corresponding to the respective drive voltages are provided with respect to the memory core 1. As a result, the four pads 91, 92, 93, and 95 configured to supply the four different drive voltages V_{CC1}, V_{CC2}, V_{CCQ}, and V_{SS} to the inside of the chip 90, including the pad 92 configured to supply the drive voltage V_{CCQ} to the I/O circuit 20 and the pad 95 configured to supply the ground voltage V_{SS} to the inside of the chip 90, are provided on the chip 90 of the flash memory 9. The pads 91, 92, 93 and 95 is connected to the each circuit through the interconnects (metal layers) in the interlayer insulating films.

The power supply lines 910, 920, 930, and 950 associated with the respective power supply pads 91, 92, 93, and 95 are provided between the voltage regulation circuit 80 and the flash memory 9.

Thereby, four power supply systems V_{CC1}, V_{CC2}, V_{CCQ}, and V_{SS} corresponding to the respective pads 91, 92, 93, and 95 and the respective power supply lines 910, 920, 930, and 950 are independently formed from each other.

As a result, the power supply system provided for the I/O circuit 20 of the flash memory 9 can be commonalized with a circuit (e.g., the controller) other than the flash memory in the memory system 200. Like the memory controller 30A, the drive voltage used to the circuit other than the flash memory in the memory system 200 can be supplied to the flash memory 9.

It is to be noted that, considering layouts of the circuits and the interconnects and IR drop, power supply pads 91, 92, 93, and 95 associated with a given drive voltage may be provided with respect to one chip. In this case, a plurality of power supply lines for a given drive voltage may be provided in accordance with the number of the power supply pads 91, 92, 93, and 95 associated with a give drive voltage and layouts of the circuits and the interconnects in the chip. Furthermore, if any two of the drive voltages V_{CC1}, V_{CC2}, and V_{CCQ} are set to the same voltage value, the power supply pads 91, 92, or 93 for a drive voltage of a given voltage value may be connected to one power supply line for the drive voltage of the given drive voltage value.

Even if the circuits are driven by using the drive voltages having the same voltage value, in regard to a drive voltage having a given intensity (a common voltage), characteristics (a design value or an allowable value of each circuit) of the circuits are often different from each other in accordance with a supply capability of a current/voltage for each circuit, an upper limit in a current amount or a current value used for operations of the circuit, a drive capability of each circuit, and others. Thus, even though setting voltage values in drive voltages are the same value in part of the circuits, it is preferable that drive voltages are supplied to respective circuits in accordance with characteristics of the circuits through the power supply pads 91, 92 and 93 and power supply lines which are separated from each other without the decrease of the number of power supply lines.

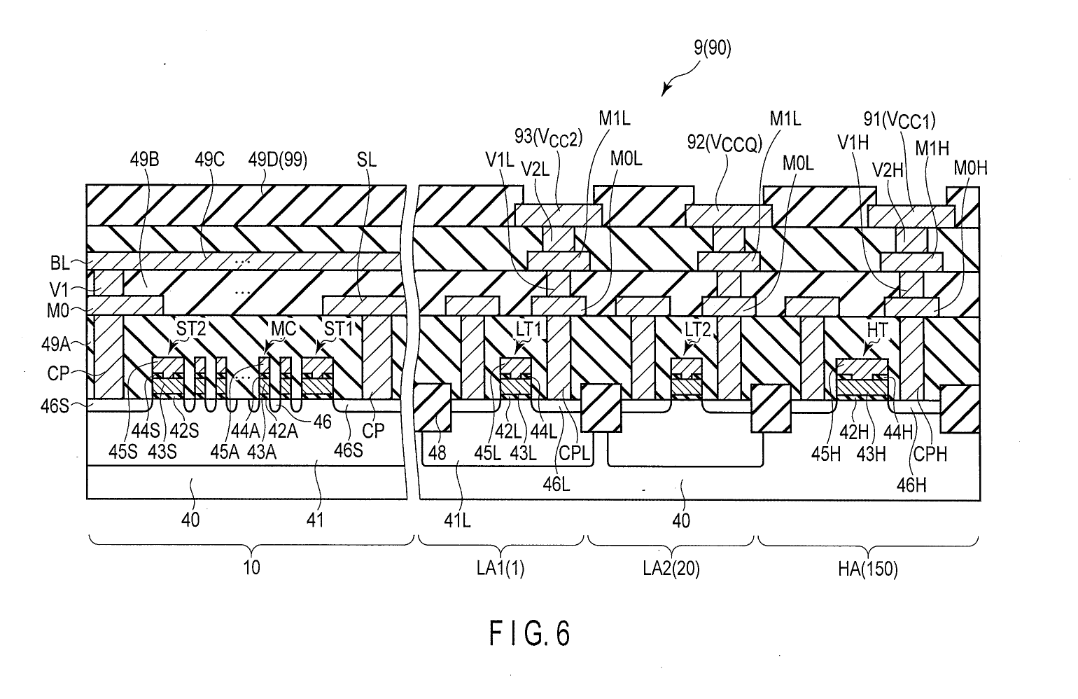

Structures of elements included in the flash memory 9 in this embodiment will now be described with reference to FIG. 6. FIG. 6 is a schematic cross-sectional view for explaining constituent elements included in the flash memory in this embodiment.

As shown in FIG. 6, the flash memory 9 includes the memory cell MC and transistors LT1, LT2, and HT having different operation characteristics (functions).

The memory cell MC is provided in the memory cell array 10 of a semiconductor substrate 40.

In the memory cell array 10, an active area AA is provided. In the memory cell array 10, the active area AA extends in a column direction (a channel length direction of a transistor, a y direction). The active area AA is sandwiched between element isolating regions (not shown) in a row direction (a channel width direction of a transistor, an x direction).

A p-type well region 41 is provided in a surface layer portion of the semiconductor substrate 40 in the memory cell array 10. The memory cell MC and the select transistors ST are provided in the active area AA in the p-type well region 41.

As described above, the memory cell MC is a field-effect transistor having a stack gate structure that includes a charge storage layer 43A and a control gate electrode 45A.

The charge storage layer 43A is provided on a gate insulating film 42 on the surface of the p-type well region 41. The gate insulating film 42 functions as a tunnel insulating film of the memory cell MC at the time of writing data. The charge storage layer 43A is formed of, e.g., a polysilicon layer or a charge trap type insulating film. In the following description, the charge storage layer 43A formed of the polysilicon layer will be referred to as a floating gate electrode.

In the memory cells MC that are adjacent to each other in the row direction, the charge storage layers 43A of the respective memory cells MC are electrically separated from each other by an element isolation insulating film (not shown) buried in the element isolating region.

An intergate insulating film 44A is provided on the charge storage layer 43A.

The control gate electrode 45A is stacked on the charge storage layer 43A through the intergate insulating film 44A. The control gate electrode 45A extends in the row direction to cut across, e.g., the charge storage layers 43A aligned in the row direction. The control gate electrode 45A is shared by the memory cells MC aligned in the row direction. The control gate electrode 45A functions as a word line WL.

In the flash memory, the memory cells MC that are adjacent to each other along the column direction in the common active area AA share a source/drain, whereby current paths (channel regions of the transistors) of the memory cells are connected in series. As a result, an NAND string including the memory cells MC is formed. For example, in the p-type well region 41, each diffusion layer (a source/drain diffusion layer) 46 as a source/drain of the memory cell MC is formed. A region between the source and the drain adjacent to each other is a channel region that functions as an electron transfer region. However, in the memory cell MC, the source/drain diffusion layer 46 may not be formed in some cases.

The select transistors ST1 and ST2 are provided at one end and the other end of the active area AA associated with the memory cell unit MC. Gate structures of the two select transistors ST1 and ST2 in the memory cell unit MU are substantially equal to each other.

Each select transistor ST is formed substantially simultaneously with each memory cell MC. A gate electrode of each select transistor ST has a stack gate structure including a lower electrode layer 43S and an upper electrode layer 45S.

A gate insulating film 42S of the select transistor ST is provided on the surface of the well region 41. The gate insulating film 42S is formed simultaneously with each tunnel insulating film 42 of the memory cell MC.

Each lower electrode layer 43S of the select transistor ST is provided on the gate insulating film 42S. Each lower electrode layer 43S is formed simultaneously with the charge storage layer 43A. The lower electrode layers 43S adjacent to each other in the row direction are electrically isolated from each other by an element isolation insulating film.

An insulator 44S having an opening portion is provided on the lower electrode layer 43S. The insulator 44S is formed simultaneously with the intergate insulating film 44A.

The upper electrode layer 45S of the select transistor ST is provided on the insulator 44S, and it is stacked on the lower electrode layer 43S to sandwich the insulator 44S. The upper electrode layer 45S is in contact with the lower electrode layer 43S through the opening portion of the insulator 44S and electrically connected with the two electrode layers 43S and 45S. The upper electrode layer 45S is formed substantially simultaneously with the control gate electrode 45A. The upper electrode layer 45S of the select transistor ST extends in the row direction and is shared by the select transistors ST aligned in the row direction. The upper electrode layer 45S functions as a select gate line.

In the well region 41, a diffusion layer 46S as a source/drain of each select transistor ST is provided. One of the two diffusion layers of each select transistor ST is shared by the source/drain of the memory cell MC at a terminal end of the NAND string. As a result, the select transistors ST are connected to the current paths of the NAND string in series, thereby forming the memory cell unit MU.

Of the two diffusion layers of each select transistor ST, the other diffusion layer 46S is connected to a contact plug CP. The select transistor ST2 at the one end of the memory cell unit MC is connected to the bit line BL, the select transistor ST1 at the other end of the memory cell unit MU is connected to the source line SL, via this contact plug CP.

On the semiconductor substrate 40, interlayer insulating films 49A, 49B, 49C, and 49D are provided to cover the memory cells MC and the select transistors ST. Each contact plug CP is formed in a contact hole formed in the interlayer insulating film 49A.

A metal layer (an intermediate interconnect) M0 is provided on the interlayer insulating film 49A and each contact plug CP. The metal layer M0 is electrically connected to the contact plug CP.

When the contact plug CP is connected to the select transistor ST2 on the drain side of the memory cell unit MC, a via plug V1 is connected to the metal layer M0. The via plug V1 is embedded in the contact hole in the interlayer insulating film 49B. The bit line BL extending in the column direction is provided on the interlayer insulating film 49B and the via plug V1. The bit line BL is connected to the select transistor ST2 on the drain side through the via plug V1, the metal layer M0, and the contact plug CP. The interlayer insulating films 49C and 49D are laminated on the bit line BL.

On the source side of the memory cell unit MU, the diffusion layer 46S of the select transistor ST1 on the source side is connected to the contact plug CP embedded in the interlayer insulating film 49A. The contact plug CP connected to the select transistor ST1 on the source side is connected to a metal layer on the same interconnect level as the intermediate metal layer M0. This metal layer functions as the source line SL, and the metal layer SL extends in the row direction. In this embodiment, the interconnect level represents a position (a height) of an interconnect in a direction vertical to the substrate surface when the surface of the semiconductor substrate 40 is determined as a reference.

It is to be noted that the memory cell MC may have a gate structure which is of an MONOS structure. In this case, the charge storage layer 43A is formed of an insulating film including a trap level for electrons like a silicon nitride film. Furthermore, in this embodiment, a flash memory in which the memory cells MC are two-dimensionally (an X-Y plane) aligned in the memory cell array 10 is shown. However, the flash memory according to this embodiment may be a flash memory (e.g., a BiCS memory) including a memory cell array having a three-dimensional structure in which the memory cells MC are two-dimensionally aligned in the memory cell array 10 and the memory cells MC are laminated in the direction vertical to the surface of the semiconductor substrate 30. Moreover, the memory according to this embodiment may be a memory including a cross-point type memory cell array 10 having a three-dimensional structure (e.g., a resistance-change memory, a phase-change memory, an ion memory, or a molecular memory).

The field-effect transistors forming the peripheral circuits 11 to 20 other than the memory cell array 10 are provided on the same semiconductor substrate 40 as the memory cell array 10. Each of the transistors forming the peripheral circuits 11 to 20 will be referred to as a peripheral transistor, and a region in the semiconductor substrate 40 where each peripheral transistor is provided will be referred to as a peripheral circuit region.

As the peripheral transistors, low-breakdown voltage transistors LT1 and LT2 each having a low threshold voltage (a breakdown voltage) and a high-breakdown voltage transistor HT having a higher threshold voltage (a breakdown voltage) than the low-breakdown voltage transistors are provided in the peripheral circuit region.

In the peripheral circuit region, regions LA1 and LA2 where the low-breakdown voltage transistors LT1 and LT2 are formed will be referred to as low-breakdown voltage transistor forming regions LA1 and LA2 and a region HA where the high-breakdown voltage transistor HV is formed will be referred to as a high-breakdown voltage transistor forming region HA hereinafter. When these forming regions LA1, LA2, an HA are not discriminated from each other, these regions will be generically called a peripheral transistor forming region. Although FIG. 6 shows the two low-breakdown voltage transistors LT1 and LT2, when these low-breakdown voltage transistors LT1 and LT2 are not discriminated from each other, they are generically called a low-breakdown voltage transistor LT. When these low-breakdown voltage transistor forming regions LA1 and LA2 are not discriminated from each other, they are generically called a low-breakdown voltage transistor forming region LA.

For example, in enhancement type peripheral transistors, the low-breakdown voltage transistor LT is driven with a threshold voltage which is approximately 0 V to 7 V in terms of an absolute value, and the high-breakdown voltage transistor HT is driven with a threshold voltage which is approximately 10 V to 30 V in terms of an absolute value. It is to be noted that each peripheral transistor may be a depletion type field-effect transistor.

Each of the peripheral transistors LT and HT has a gate structure similar to that of the select transistor ST.

Each of the peripheral transistors LT and HT is provided in the active area partitioned by each element isolation insulating film 48 in the element isolating region.

A well region 41L is provided in the active area where the low-breakdown voltage transistor LT is provided. For example, in the active area where the high-breakdown voltage transistor HT is provided, the well region is not provided. The active area of the high-breakdown voltage transistor HT is an intrinsic region that hardly contains impurities (an n-type or p-type dopant) that provides the semiconductor with conducting properties.

Gate insulating films 42L and 42H of the peripheral transistors LT and HT are provided on the surface of the active area (the well region).

The gate insulating film 42L of the low-breakdown voltage transistor LT is formed substantially simultaneously with, e.g., the gate insulating films 42A and 42S of the memory cell MC and the select transistor ST.

The gate insulating film 42H of the high-breakdown voltage transistor HT has a film thickness larger than those of the gate insulating films 42A, 42S, and 42L of the memory cell MC, the select transistor ST, and the low-breakdown voltage transistor LT. As a result, a higher breakdown voltage than those of the other transistors MC, ST, and ST is assured for the high-breakdown voltage transistor HT. A gate insulating film 42H of the high-breakdown voltage transistor HT is formed in a process different from, e.g., those of the gate insulating films 42A, 42S, and 42L of the memory cell MC, the select transistor ST, and the low-breakdown voltage transistor LT.

Gate electrodes of the peripheral transistors LT and HT are provided on the gate insulating films 42L and 42H, respectively. Like the select transistor ST, each of the gate electrodes of the peripheral transistors LT and HT has a gate structure in which a lower electrode layer 43L or 43H and an upper electrode layer 45L or 45H are stacked to sandwich an insulator 44L or 44H having an opening portion therebetween.

The lower electrode layers 43L and 43H of the gate electrodes of the peripheral transistors LT and HT are provided on the gate insulating films 42L and 42H, respectively. The lower electrode layers 43L and 43H are formed simultaneously with the charge storage layer 43A of the memory cell MC.

Each insulator 44L and 44H having the opening portion OP is provided on each lower electrode layers 43L and 43H of each peripheral transistor LT or HT. The insulators 44L and 44H are formed substantially simultaneously with the intergate insulating film 44A of the memory cell MC, and the opening portions of the insulators 44L and 44H are formed simultaneously with the insulator 44S included in the select transistor ST.

The upper electrode layer 45L and 45H of the gate electrode of the peripheral transistor LT or HT is stacked on the lower electrode layer 43L and 43H through the insulator 44L and 44H. A portion of the upper electrode layer 45L and 45H is in contact with the lower electrode layer 43L and 43H through the opening portion of the insulator 44L and 44H. The upper electrode layers 45L and 45H are formed substantially simultaneously with the control gate electrode 45A of the memory cell MC.

Of the peripheral transistors LT and HT, the high-breakdown voltage transistor HT has a gate length (a channel length) and a gate width (a channel width) larger than those of the select transistor ST and the low-breakdown voltage transistor LT in order to assure a high-breakdown voltage and transfer a relatively high voltage (e.g., 25 V) like a write voltage to the word line WL. It is to be noted that the two low-breakdown voltage transistors LT1 and LT2 may have different gate lengths and different gate widths.

As a source/drain of each peripheral transistor LT and HT, a diffusion layer (a source/drain diffusion layer) 46L and 46H is provided in the active area of each low-breakdown voltage/high-breakdown voltage transistor forming region LA and HA.

Contact plugs CPL and CPH are connected to the diffusion layers 46L and 46H, respectively. The contact plugs CPL and CPH are embedded in contact holes formed in the interlayer insulating film 49A. The contact plugs CPL and CPH are connected to interconnects M0L and M0H on the interlayer insulating film 49A, respectively. The interconnects M0L and M0H are placed on the same interconnect level as the intermediate interconnect M0 in the memory cell array 2. To form predetermined circuits, the intermediate interconnects M0L and M0H of the peripheral transistors LT and HT are connected to intermediate interconnects M0L and M0H provided on an upper interconnect level through via plugs V0L and V1H, respectively.

The contact plugs (not shown) are connected to the upper electrode layers 45L and 45H of the gate electrodes of the peripheral transistors LT and HT and gate voltages are applied to the gate electrodes of the peripheral transistors LT and HT, respectively.

As elements other than the peripheral transistors LT and HT, for example, capacitors (capacitive elements) are provided on the semiconductor substrate 40. The capacitors (not shown) are used to form charge pumps of the potential generation circuit 15 and the high-voltage generator 150. An MOS capacitor is used as a capacitor in the potential generation circuit 15, and it has a structure that is similar (substantially equal) to the peripheral transistor (e.g., the high-breakdown voltage transistor HT).

It is to be noted that, in this embodiment, the gate electrodes of the peripheral transistors LT and HT have substantially the same structures as those of the memory cell MC and the select transistor ST, respectively. However, the gate electrodes of the peripheral transistors LT and HT may be formed of one continuous conductive layer, differing from the gate structures of the memory cell MC and the select transistor ST. In this case, the peripheral transistors LT and HT are formed in a process different from those of the memory cell MC and the select transistor ST.

The pads 91, 92, and 93 are provided on the uppermost layers of the interlayer insulating films 49C and 49D laminated on the semiconductor substrate 40, drive voltages V_{CC1}, V_{CC2} and V_{CCQ} are supplied to the pads 91, 92, and 93, respectively.

The power supply pad 91 to which the drive voltage V_{CC1} is supplied is connected to a source/drain diffusion layer 46H of the high-breakdown voltage transistor HT through the via plugs V1H and V2H and the intermediate interconnects M1H and M0H in the interlayer insulating films 49A to 49D. The high-breakdown voltage transistor HT connected to the power supply pad 91 for the drive voltage V_{CC1} is, e.g., a transistor HT that forms a high-voltage drive circuit group, the high-potential generator 150 in the potential generation circuit 15, or the row control circuit 11 in the memory core 1.

The power supply pad 92 to which the drive voltage V_{CCQ} lower than the drive voltage V_{CC1} is supplied is connected to the source/drain diffusion layer of the low-breakdown voltage transistor LT2 that forms the I/O circuit 20 through the via plugs and the intermediate interconnects in the interlayer insulating films 49A to 49D.

For example, the power supply pad 93 to which the drive voltage V_{CC2} having an intensity (a voltage value) intermediate between the drive voltage V_{CC1} and the drive voltage V_{CCQ} is supplied is connected to a source/drain diffusion layer 46L of the low-breakdown voltage transistor LT1 through the via plugs V1L and V2L and the intermediate interconnects M1L and M0L in the interlayer insulating films 49A to 49D. The low-breakdown voltage transistor LT1 connected to the power supply pad 93 for the drive voltage V_{CC2} is the transistor LT1 that forms a constituent element in the low-voltage drive circuit group 5 in the memory core 1, e.g., the address buffer 110 and 120 in the row/column control circuit 11 and 12, the internal control circuit 18, or the register 171, 190, or 191.

It is to be noted that FIG. 6 shows a correspondence relationship between the drive voltages V_{CC1}, V_{CC2}, and V_{CCQ} having different intensities and the circuits to which these voltages are supplied alone, and the pads associated with the respective drive voltages VCC₁, V_{CC2}, and V_{CCQ} may not be directly connected to the low-breakdown voltage transistors LT or the high-breakdown voltage transistors HT, and other transistors having different threshold voltages may be provided between the low-breakdown voltage/high-breakdown voltage transistors LT and HT and the pads 91, 92 and 93. In accordance with the internal configuration of the flash memory 9, the power supply pad 91 to which the drive voltage V_{CC1} is supplied may be connected to the low-breakdown voltage transistor LT, or the power supply pad 93 to which the drive voltage V_{CC2} is supplied may be connected to the high-breakdown voltage transistor HT. Furthermore, the power supply pads 91, 92, and 93 may be connected to elements in the flash memory 9 other than the peripheral transistors LT and HT such as MOS capacitors without using the transistors LT and HT.

Although FIG. 6 shows the power supply pads 91, 92, and 93 to which the drive voltages VCC₁, V_{CC2}, and V_{CCQ} are supplied alone, the I/O pads 94 and a ground pad to which a ground voltage is supplied are provided on the same interconnect level as the power supply pads 91, 92, and 93. It is to be noted that FIG. 6 shows that the pads and the elements overlap in the direction vertical to the semiconductor substrate surface, but these members are shown in this way to clarify the illustration and explanation. Elements like the peripheral transistors may not be arranged in the semiconductor region immediately below each pad.

The memory controller 30A controls an operation of the flash memory 9. The memory controller 30A includes a core circuit (which will be referred to as a controller core hereinafter) 301 serving as a primary part of the controller.

The memory controller 30A includes an interface (an I/O circuit) 302 configured to transmit/receive information between the controller core 301 and the flash memory 9 and an interface (an I/O circuit) 303 configured to transmit/receive information between controller core 301 and the host device 30B. However, the interfaces 302 and 303 may be provided outside the memory controller 30A.

A register 304 is connected to the controller core 301. The register 304 temporarily holds a signal obtained by internal processing of the controller core 301, information (a signal) from the controller core 301 to the host device 30B or information from the host device 30B to the controller core 301 that is input/output through the interface 303.

Furthermore, a register 305 is connected to the interface 302 on the memory 9 side. The register 305 temporarily holds information from the flash memory 9 for the controller core 301 (a control signal or read data) or information from the controller core 301 for the flash memory 9 (a control signal or write data) that is input/output through the interface 302.

The controller core 301 generates a signal configured to control an operation of the flash memory 9 based on information from the host device 30B. The controller core 301 generates a signal that informs the host device 30B of an operation result/operation status of the flash memory 9 based on a signal indicative of an operation result and an operation status from the flash memory 9.

The controller core 301 converts a logical address from the host device 30B into a physical address. The logical address is an address managed by the host device 30B, and the physical address is a real address that is managed by the memory card 40 (the memory controller 30A).

The memory card 40 supplies or receives information with respect to the host device 30B provided outside the memory card 40 through a connector based on a compliant standard set for the interface 303, e.g., the universal serial bus (USB) standard or the eMMC standard.

A command, a clock signal, data transferred between the memory card and the host device, and a signal associated with an operation mode of data transfer are input to or output from the connector. For example, the operation mode of data transfer is specified based on a standard of the memory card (e.g., an SD card) 40, and an SD mode, an SPI mode, or the like is used as the operation mode of the memory card.

A connector 401 to which the power supply voltage V_{DD} is supplied among the connectors, is provided in the memory card 40. Further, a connector 409 to which the ground voltage V_{SS} is supplied is provided in the memory card 40.

The voltage regulation circuit 80 is provided on the circuit substrate of the memory card 40 on which the flash memory 9 is mounted as a package separated from the package of the memory.

The voltage regulation circuit 80 includes power supplies (power supply terminals) 81 and 82 that serve as supply sources of the voltage V_{DD} and the ground voltage V_{SS} as well as a step-down unit 85. The voltage regulation circuit 80 lowers the voltage V_{DD} by using the step-down unit 85, thereby generating the drive voltages V_{CC2} and V_{CCQ} which are smaller than the voltage V_{DD} (the drive voltage V_{CC1}).

For example, a voltage regulation circuit 80 is provided in the memory card 40 to be connected to the connectors 401 and 409 to which the voltages V_{DD} and V_{SS} are applied. As a result, the voltage regulation circuit 80 has the two power supplies V_{DD} and V_{SS}. It is to be noted that FIG. 2 shows that the voltage regulation circuit 80 is provided separately from the respective chips 9 and 30A. However, the voltage regulation circuit 80 may be provided, e.g., in the chip of the memory controller 30A.

The voltage regulation circuit 80 in the memory card 40 adjusts (boosts or decreases) a voltage value of the voltage V_{DD} input to the inside of the memory card 40 through the connector 401. As a result, the drive voltages V_{CC1}, V_{CC2}, and V_{CCQ} supplied to the flash memory 9 and the memory controller 30A are generated. The generated drive voltages V_{CC1}, V_{CC2}, and V_{CCQ} are output to the respective circuits in the respective chips 9 and 30A. Moreover, the voltage regulation circuit 80 outputs the ground voltage V_{SS} to the respective chips 9 and 30A through a power supply line 950, and the ground voltage V_{SS} is supplied to the respective circuits in the chips 9 and 30A.

The voltage regulation circuit 80 outputs the three drive voltages V_{CC1}, V_{CC2}, and V_{CCQ} to the flash memory 9. The respective drive voltages V_{CC1}, V_{CC2}, and V_{CCQ} are supplied to the respective circuits in the flash memory 9 by power supply systems (power supply pads and power supply lines) that are independent from each other.

The drive voltage V_{CC1} (e.g., 3.3 V) is supplied to the high-voltage drive circuit group (the potential generation circuit, the high-voltage generator) 15 in the memory core 1 through the power supply line 910 and the power supply pad 91 provided in the chip of the flash memory 9. Additionally, the drive voltage V_{CC2} (e.g., 1.8 V) lower than the drive voltage V_{CC1} is supplied to the low-voltage drive circuit group (e.g., the internal control circuit or the buffer) in the memory core 1.

As a drive voltage for the memory controller 30A, the drive voltage V_{CCQ} is output from the voltage regulation circuit 80 to the memory controller 30A. The drive voltage V_{CCQ} (e.g., 1.5 V) for the memory controller 30A is lower than the drive voltages V_{CC1} and V_{CC2} supplied to the memory core 1 of the flash memory 9. The drive voltage V_{CCQ} is supplied to each of the controller core 301, the interfaces 302 and 303, and the registers 304 and 305 through pads 309A, 309B, and 309C for supplying voltages provided in the memory controller 30A.

In the memory card 40 as the memory system 200 according to this embodiment, the drive voltage V_{CCQ} for the memory controller 30A is supplied to the memory controller 30A and also supplied to the I/O circuit (the interface) 20 of the flash memory 9.

It is to be noted that the drive voltage V_{CCQ} can be supplied to one pad of the memory controller 30A and the supplied voltage V_{CCQ} can be distributed to the controller core 301, the interfaces 302 and 303, and the registers 304 and 305 through interconnects connected to one pad in the memory controller 30A.

On the other hand, the voltage V_{DD} supplied to the connector 401 may be directly supplied to the high-voltage drive circuit group 15 of the memory core 1 as the drive voltage V_{CC1}. Furthermore, the drive voltage V_{CCQ} for the I/O circuit 20 may be supplied to the I/O circuit 20 of the flash memory 9 through the voltage regulation circuit and the power supply system (a power supply line) provided in the memory controller 30A. Moreover, the flash memory 9 may supply the drive voltages V_{CC2} and V_{CCQ} to the memory controller 30A.

Like this embodiment, in a case where the power supply voltage different from that of the memory core 1 is supplied to the I/O circuit 20 of the flash memory 9 mounted in the memory card 40, the drive voltage V_{CCQ} supplied to the I/O circuit 20 is set to the same intensity as that of the drive voltage V_{CCQ} supplied to the memory controller 30A mounted in the memory card 40. Therefore, like this embodiment, even if the drive voltage V_{CCQ} having an intensity different from that of the drive voltage V_{CC1} and V_{CC2} of the memory core 1 in the flash memory 9 is supplied to the I/O circuit 20 of the flash memory 9, the internal configuration (e.g., connectors or internal interconnects) of the memory card 40 does not have to be completely changed.

Further, the drive voltage V_{CCQ} supplied to the I/O circuit 20 and the memory controller 30A may be supplied to the low-voltage drive circuit group 5 of the memory core 1 in place of the drive voltage V_{CC2}.

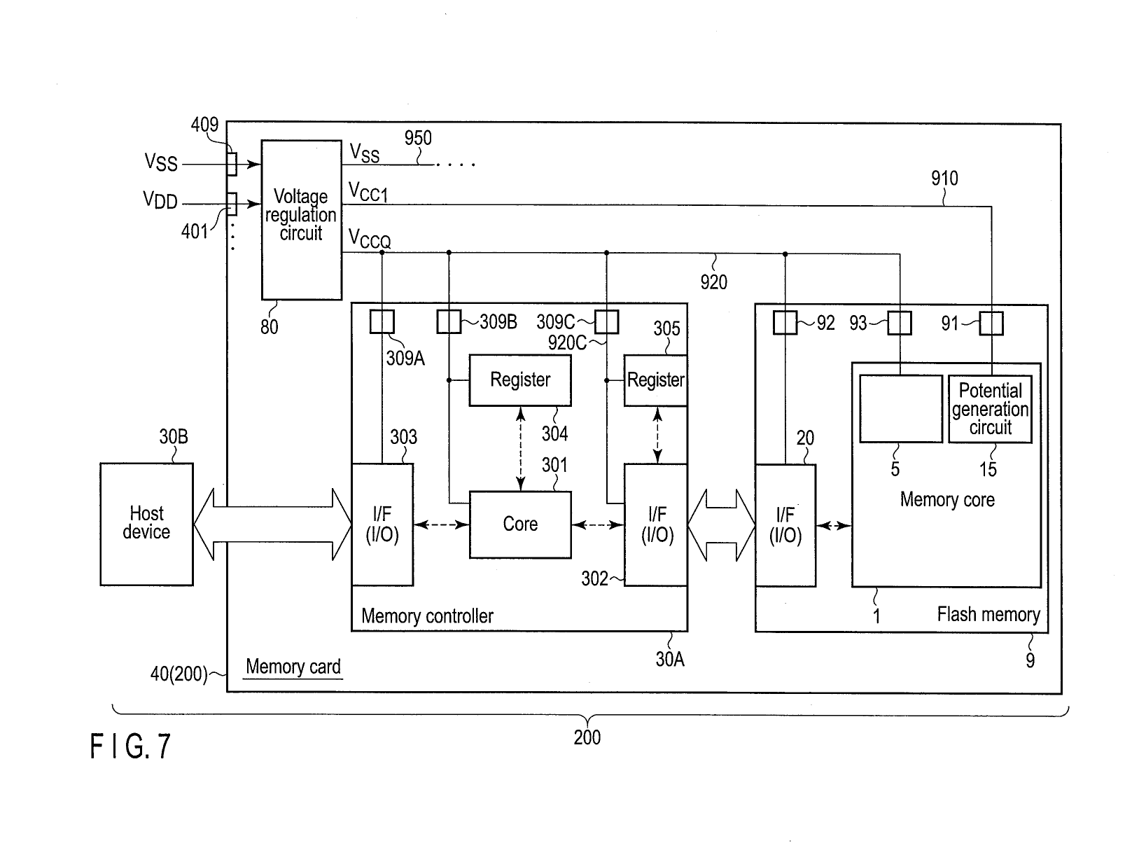

As shown in FIG. 7, the voltage regulation circuit 80 may output the two drive voltages V_{CC1} and V_{CCQ} to the two power supply systems (the power supply lines) that are independent from each other. For example, in a memory system based on the eMMC standard, the number of the power supply systems (the power supply lines) inside the memory system is specified as two. In this case, as the first drive voltage, the drive voltage V_{CC1} (e.g., approximately 3.3 V) is supplied to the high-voltage drive circuit group 15 in the memory core 1 of the flash memory 9. Additionally, as the second and third drive voltages, the drive voltage V_{CCQ} (e.g., approximately 1.8 V) lower than the drive voltage V_{CC1} is supplied to the memory controller 30A, the I/O circuit 20 and the low-voltage drive circuit group 5 of the flash memory 9 in common.

Like the flash memory 9 of the memory system according to this embodiment, when the power supply pads 91, 92 and 93 for the drive voltages are electrically separated from each other, for both of a case where the number of the power supply lines and the drive voltages in the memory system 200 is restricted such as the memory card 40 of FIG. 7 and a case where more power supplies (drive voltages) are used to the memory system 200, compatibility of the flash memory (chip) for the power supply systems in the memory system 200 can be improved.

It is to be noted that a voltage higher than 3.3 V may be used to a voltage supplied to the power supply pad 91 for the high-voltage drive circuit group of the memory core 1 (for example, the potential generation circuit 15).

As the drive voltage V_{CC2} supplied to the power supply pad 93 for the low-voltage drive circuit group 5 of the memory core 1, a voltage lower than the drive voltage V_{CC1} is used, and a voltage of, e.g., approximately 1.5 V to 1.8 V is adopted. However, the drive voltage V_{CC2} supplied to the low-voltage drive circuit group 5 may be a voltage higher than 1.8 V (e.g., 2.5 V to 3.3 V) or a voltage lower than 1.5 V (e.g., 1.2 V) in accordance with specifications of a user.

It is preferable that a voltage lower than the drive voltage V_{CC2} is used for the drive voltage V_{CCQ} supplied to the power supply pad 92 for the I/O circuit 20. For example, when the drive voltage V_{CC2} is 1.8 V, a voltage lower than 1.8 V, e.g., 1.5 V is used as the drive voltage V_{CCQ}. When the drive voltage V_{CC2} is 1.5 V, a voltage lower than 1.5 V, e.g., 1.2 V is used as the drive voltage V_{CCQ}.

If the drive voltage V_{CCQ} of the I/O circuit 20 is lower than the drive voltage V_{CC1} of the potential generation circuit 13, the drive voltage Vow of the I/O circuit 20 may be set to a voltage substantially equal to the drive voltage V_{CC2} of the low-voltage drive circuit group 5, (e.g., a voltage of approximately 1.5 V to 2.5 V), or the drive voltage V_{CC1} of the potential generation circuit 15 may be set to a voltage substantially equal to the drive voltage V_{CC2} of the low-voltage drive circuit group 5.

Furthermore, a boosting circuit may be provided in the flash memory 9, the drive voltage V_{CCQ} may be boosted to the drive voltage V_{CC2}, and the boosted voltage may be supplied to the low-voltage drive circuit group 5.

It is to be noted that four or more power supply systems may be formed in the memory card 40 and the flash memory 9 in association with four or more drive voltages (>V_{SS}) having different intensities.

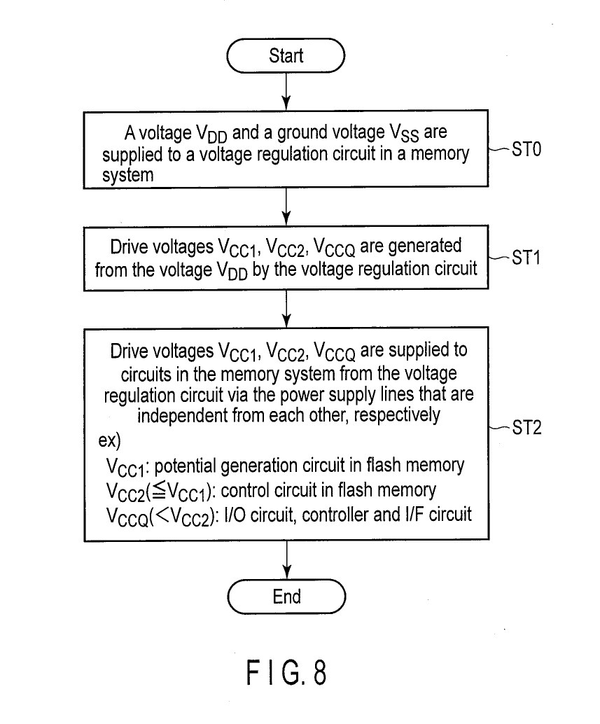

For example, by an operation of the memory card 40 as the memory system shown in FIG. 8, voltages supplied to the memory controller 30A and flash memory 9 from the voltage regulation circuit 80 are generated.

FIG. 8 is a flow chart explaining for the control method of the memory system according to this embodiment. Internal drive voltages V_{CC1}, V_{CC2} and V_{CCQ} in the memory card 40 are generated by a voltage regulation circuit 80 in the memory card 40 based on the operation shown in FIG. 8.

A voltage (e.g., 3.3V) V_{DD} having a given intensity is input to the voltage regulation circuit 80 in the memory system (herein, a memory card) (step ST0).

In accordance with three or more power supply systems provided in the memory card 40 and the flash memory 9, the intensity of the voltage V_{DD} input to the memory card 40 is regulated, thereby drive voltages V_{CC1}, V_{CC2} and V_{CCQ} are generated (step ST1).

Each generated drive voltage V_{CC1}, V_{CC2} and V_{CCQ} is supplied to components of the memory card 40 and circuits in the flash memory 9 through power supply lines 910, 920 and 930 which are provided in the memory system 200 and are electrically independent from each other and power supply pads 91, 92 and 93 which are provided in the flash memory 9 and are electrically independent from each other (step ST2). For example, the drive voltage V_{CCQ} of approximately 1.2 V is supplied to a memory controller 30A and interfaces 303 and 302 in the memory card 40. In the internal circuit of the flash memory 9, the drive voltage V_{CC1} of approximately 3.3 V is supplied to the potential generating circuit 15, and the drive voltage V_{CCQ} of approximately 1.2V to 1.5 V is supplied to the I/O circuit 20 in the flash memory 9. Further, the predetermined drive voltage V_{CC2}, for example, between 1.2 V and 3.3 V (i.e., 1.5 V to 1.8 V) is supplied to the low-voltage drive circuit group 5 in the flash memory 9 in accordance with the specification of the flash memory.

Thereby, the memory system 200 according to this embodiment is driven by the drive voltages V_{CC1}, V_{CC2} and V_{CCQ} generated by the voltage regulation circuit 80.

As shown in FIG. 2 to FIG. 7, in the flash memory 9 in the memory system 200 according to this embodiment, the power supply pad 92 for the I/O circuit 20 is provided separately from the power supply pads 91 and 93 for the memory core 1.

The memory system 200 includes the power supply lines 910, 920, and 930 which are electrically separated from each other, the flash memory 9 in the memory system 200 includes the power supply pads 91, 92, and 93 which are electrically separated from each other, and the power supply systems corresponding to the power supply pads 91, 92, and 93 are provided in the flash memory 9. The drive voltages V_{CC1}, V_{CC2} and V_{CCQ} supplied to the memory system 200 and the flash memory 9 in this embodiment are generated by the regulation circuit 80 in the memory system 200.

To reduce the power consumption of the memory system 200 and the flash memory 9, when a voltage supplied to the entire flash memory is reduced, a voltage supplied to the potential generation circuit 15 in the chip 90 is decreased. In this case, to generate a high voltage used for writing or reading in the flash memory 9 by boosting this small voltage, the number or areas of the high-breakdown voltage transistors HT and the capacitors (MOS transistors) included in the potential generation circuit 15 are increased. An area of the potential generation circuit 15 in the chip 90 is enlarged, and a chip size is increased. As a result, a chip cost of the flash memory 9 may possibly increase.

On the other hand, as described in this configuration example, the flash memory 9 in the memory system 200 according to this embodiment can supply appropriate voltages for the driving of each circuit 10 to 20 in flash memory 9 to each of the circuits by the power supply pads 91, 92, and 93 which are separated from each other and the power supply systems in the chip which are independent from each other.

In the flash memory 9 in the memory system 200 according to this embodiment, like the potential generation circuit 15 of the memory core 1, the highest drive voltage V_{CC1} in the drive voltages V_{CC1}, V_{CC2}, and V_{CCQ} supplied from the power supply pads (the power supply systems) 91, 92, and 93 that are independent from each other in the chip 90 is supplied to each circuit to which a relatively high voltage is preferably supplied in the flash memory 9.

As a result, it is possible to suppress an increase in the number and the areas of the elements in the potential generation circuit 15 that generates a predetermined internal voltage by boosting the supplied voltage, whereby an area and a chip size of the potential generation circuit 15 can be prevented from increasing. Consequently, in the flash memory in this embodiment, an increase in manufacturing cost of the flash memory can be suppressed.

In the flash memory 9 of the memory system 200 according to this embodiment, like the I/O circuit 20, by using the different power supply systems with respect to the I/O circuit 20 and the memory core 1, the lowest drive voltage V_{CCQ} in the drive voltages V_{CC1}, V_{CC2}, and V_{CCQ} supplied to the power supply pads 91, 92, and 93 in the chip 90 is supplied to each circuit which can be driven with a relatively low voltage in the flash memory 9.

Therefore, as compared with a case where the same voltage as the drive voltage V_{CC1} supplied to the memory core 1 (the potential generation circuit 15) is supplied to the I/O circuit 20, power consumption of the I/O circuit 20 can be selectively reduced without deterioration in operation characteristics caused due to a reduction in application voltage, an increase in number of elements and a change in circuit configuration required for maintaining predetermined operation characteristics in each circuit that is preferably driven with a relatively high voltage like the potential generation circuit 15.

As a result, the memory system 200 according to this embodiment and the flash memory 9 in the memory system 200 can reduce the power consumption.

Moreover, in the memory system 200 according to this embodiment, the drive voltage V_{CC2} having an intensity intermediate between the drive voltage V_{CCQ} of the I/O circuit 20 and the drive voltage V_{CC1} of the potential generation circuit (the high-voltage drive circuit group) 15 is supplied to the low-voltage drive circuit group 5 of the memory core 1 in the flash memory 9. When the independent power supply pad (the power supply system) 93 are provided with respect to the low-voltage drive circuit group 5, a voltage having an intensity equal to that of the drive voltage V_{CCQ} used for the I/O circuit 20 can be supplied to the low-voltage drive circuit group 5 of the memory core 1 or the drive voltage V_{CC1} used for the potential generation circuit 15 can be supplied to the same in accordance with specifications of a user. That is, one selected from the two ore more drive voltages V_{CC1}, V_{CC2}, and V_{CCQ} having the different intensities can be supplied to the low-voltage drive circuit group 5 in the memory core 1 of the flash memory 9 in the memory system 200 according to this embodiment in accordance with specifications of a user, the low-voltage drive circuit group 5 can be driven by the supplied drive voltage.

In this manner, when the drive voltages V_{CC1} and V_{CC2} for the memory core 1 can be selected in accordance with specifications of a user, a reduction in power consumption of the chip, stabilization of drive characteristics of the memory, or securement of compatibility with conventional devices can be achieved in accordance with a user's request for the memory system 200 and the flash memory 9.

As described above, in the memory system according to this embodiment, the power consumption of the memory can be reduced, and deterioration of operation characteristics of the memory can be suppressed.

(b) SSD

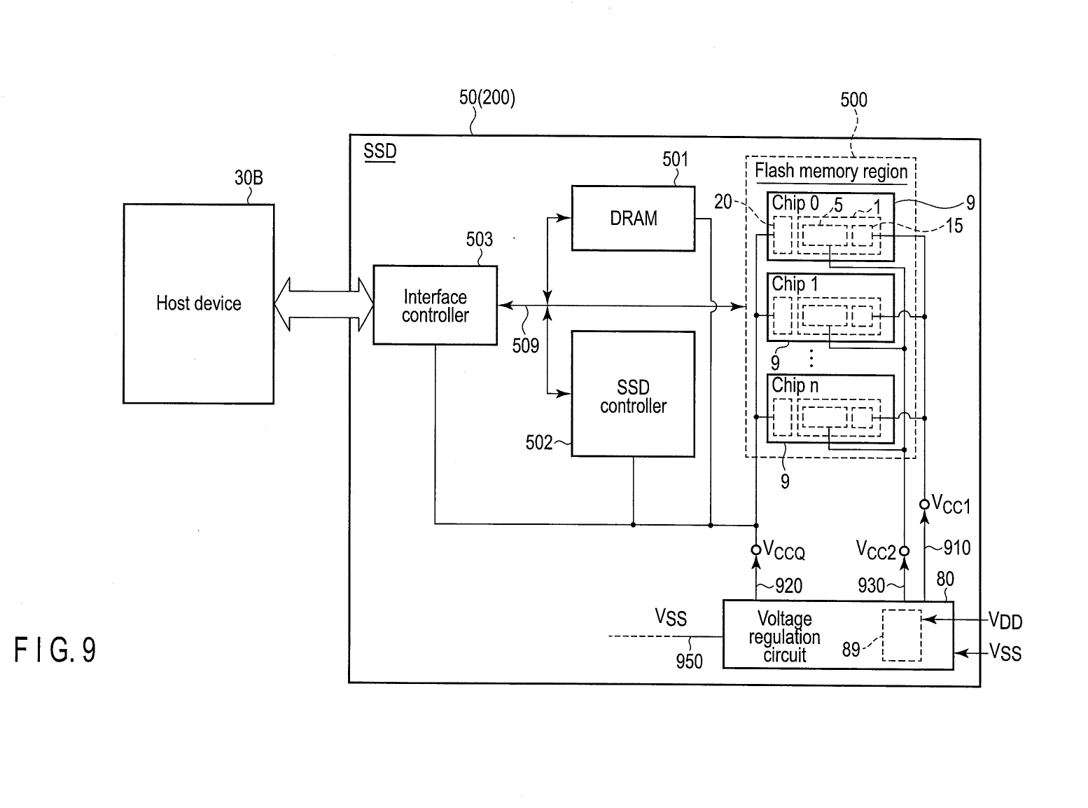

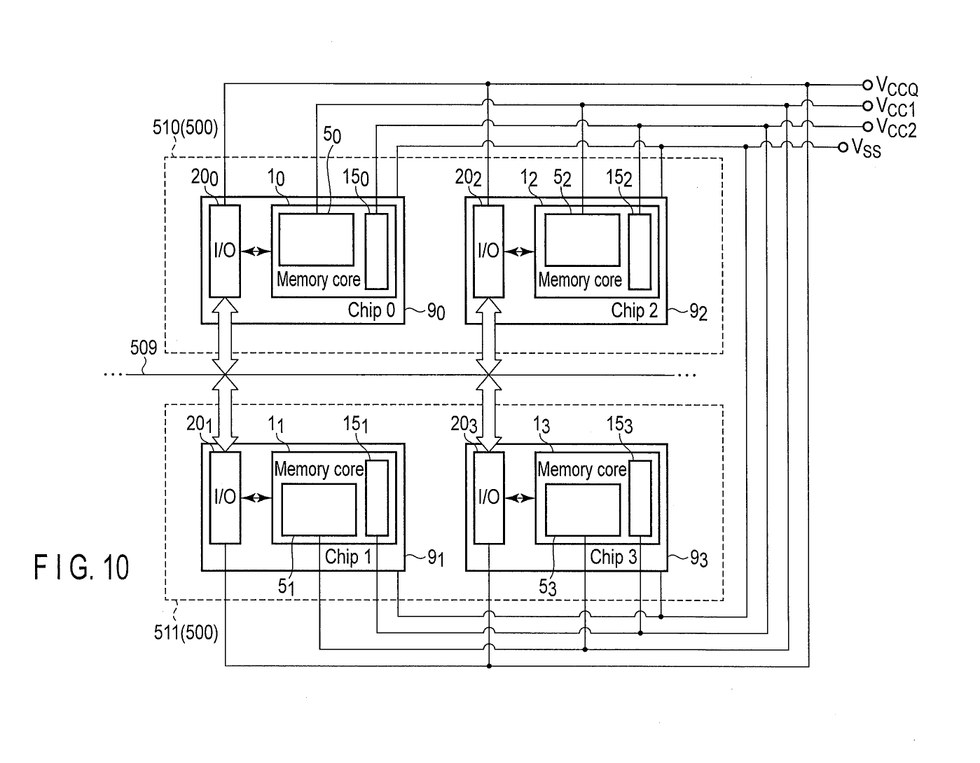

A configuration example of the memory system according to this embodiment will now be described with reference to FIG. 9 and FIG. 10.

FIG. 9 shows an internal configuration example of an SSD as one configuration example of the memory system 200 according to this embodiment.

As shown in FIG. 9, the SSD as the memory system 200 according to this embodiment is connected to a host device (an information processing device) 30B.

The SSD 50 includes a nonvolatile memory region 500 including at least one chip of flash memory (e.g., an NAND flash memory) 9, a volatile memory region 501 including one or more chip of DRAM 501, an SSD controller 502, an interface controller 503, buses (e.g., data buses and power supply buses) 509, 910, 920, 930, and 950 that connect these members, and a voltage regulation circuit 80.

It is to be noted that FIG. 9 shows that each package of flash memory 9 in the nonvolatile memory region 500 includes one chip in this way to clarify the illustration. However, MCPs including chips of the flash memory 9, respectively, may be provided in the nonvolatile memory region 500.

The interface controller 503 executes interface processing between the respective constituent units 500, 501, and 502 in the SSD 50 and the external host device 30B.

The interface controller 503 executes the interface processing based on, e.g., a standard set for the SSD. For example, the SSD 50 is connected to the host device 30B based on a communication interface conforming to the SATA standard and executes the interface processing conforming to the SATA standard. The interface standard of the SSD 50 may be serial attached SCSI (SAS) or USB besides SATA. The interface controller 503 includes, e.g., an interface circuit.

The SSD controller 502 controls various operations (e.g., wear leveling or defective block processing) of the entire SSD 50. The SSD controller 502 reads a program or data stored in the flash memory 9 as the nonvolatile memory region 500 into the DRAM 501 as the volatile memory region. The SSD controller 502 executes predetermined processing with respect to the read data and creates various kinds of tables in the DRAM 501. The SSD controller 502 receives a command such as a write command, a read command, or an erase command from the host device 30B and executes predetermined processing with respect to the flash memory 9 in response to this command. The SSD controller 502 includes, e.g., an interface circuit. The SSD controller 502 has memory controllers for controlling the each flash memory 9. It is to be noted that the memory controller may be provided outside the SSD controller 502 in accordance with each chip (package) of flash memory 9.

The DRAM 501 as the volatile memory region functions as, e.g., a data transfer cache between the host device 30B and the flash memory 9 or a work memory for the SSD controller 502. It is to be noted that the DRAM 501 may be used as a main memory in the SSD.

The DRAM 501 as the work memory temporarily stores a program and data read from the flash memory 9 at the time of startup of the SSD, a management table or a function for processing based on the program and the data, external data that is to be written into the flash memory 9, and others. The DRAM 501 includes a region where the management table is stored and a region where the function is stored. In place of the DRAM, a memory such as a static RAM (SRAM), a magnetoresistive RAM (MRAM), or a phase change RAM (PCRAM) may be used. As the work memory, using a random access memory is desirable. It is to be noted that the DRAM 501 may be mounted on a circuit substrate as an independent chip or it may be mounted in the SSD controller as a built-in memory.

The nonvolatile memory region 500 is formed by using chips Chip<0> to Chip<n> of (n+1) flash memories 9. n is an integer that is not smaller than 0. As described above, each flash memory 9 includes the I/O circuit 20 and the memory core 1 including the potential generation circuit 15 and the low-voltage drive circuit group 5.

When the host device 30B transmits a command to the SSD 50, this command is transferred to the SSD controller 502 through the interface controller 503. The SSD controller 502 processes the received command. At this time, the SSD controller 502 makes reference to the management table in the DRAM 501, and the SSD controller 502 appropriately converts a logical address from the host device 30B into a physical address managed by the SSD 50.

The SSD 50 includes the voltage regulation circuit 80 to which the external power supply voltages V_{DD} and V_{SS} are supplied in addition to the above-described respective components. By the same operation as the operation explained using FIG. 8, the voltage regulation circuit 80 generates the internal voltages (the drive voltages) V_{CC1}, V_{CC2}, and V_{CCQ} and the ground voltage V_{SS} for driving the respective memories 500 and 501 and the respective controllers 502 and 503 from the external power supply voltages V_{DD} and V_{SS} and outputs the generated voltages.

For example, as the power supply voltage V_{DD} input from the outside to the inside of the SSD 50, a voltage of 3.3 V may be used, or a voltage higher than 3.3 V, e.g., a voltage of approximately 5 V to 12 V may be used. The voltage regulation circuit 80 of the SSD 50 includes, e.g., a DC/DC converter 89. The DC/DC converter 89 can freely set intensities of the power supply voltage V_{DD} input from the outside of the SSD and each of the voltages V_{CC1}, V_{CC2}, and V_{CCQ} supplied to the inside of the SSD.

As described above, for example, the drive voltage V_{CC1} that is approximately 3.3 V is supplied to the potential generation circuit 15 of the flash memory 9, i.e., the high-voltage generator in the potential generation circuit 15, and the drive voltage V_{CC2} (e.g., 1.5 V to 1.8 V) that is not higher than the drive voltage V_{CC1} is supplied to the low-voltage drive circuit group 5 of the memory core 1.

Further, the drive voltage V_{CCQ} (e.g., 1.2 V to 1.5 V) lower than the drive voltage V_{CC1} supplied to the potential generation circuit 15 of the flash memory 9 is supplied to the I/O circuit 20 in the chip of the flash memory 9. Furthermore, the drive voltage V_{CCQ} is supplied to the interface controller 503, the DRAM 501, and the SSD controller 502 of the SSD 50.

It is to be noted that different voltages may be supplied to the DRAM 501 and the respective controllers 502 and 503 in the SSD 50. For example, the drive voltage V_{CC2} that is approximately 1.8 V is supplied to the DRAM 501 through the power supply line 930, and the drive voltage V_{CCQ} that is, e.g., approximately 1.2 V is supplied to the controllers 502 and 503 through the power supply line 920.

It is to be noted that four or more power supply systems (power supply lines) that are independent from each other may be formed in the SSD 50 in order to use four or more drive voltages (>V_{SS}, which are absolute values).

Even when the memory system 200 is the SSD 50, since the drive voltage V_{CCQ} used for the DRAM 501 and the controllers 502 and 503 in the SSD 50 is supplied to the I/O circuit 20 of the flash memory 9, the internal configuration of the SSD 50 does not have to be greatly changed.

The chips (the packages) Chip<0> to Chip<n> of the flash memories 9 in the SSD 50 may be formed in the SSD 50 to enable a parallel operation, e.g., an interleaving operation.

Like the SSD 50, when the chips (or MCP) of the flash memories 9 are included, for example, as shown in FIG. 10, the interleaving operation is carried out with respect to even-numbered flash memories 9₀ and 9₂ and odd-numbered flash memories 9₁ and 9₃ under control of the SSD controller 502. For example, control units (which will be referred to as memory groups hereinafter) 510 and 511 for the interleaving operation are set with respect to the even-numbered and odd-numbered flash memories 9₀, 9₁, 9₂, and 9₃, respectively.

It is to be noted that the description has been given as to the example where the two memory groups 510 and 511 are provided as the control units for the interleaving operation in the nonvolatile memory region 500 formed by using the flash memories 9, but three or more memory groups may be set in the nonvolatile memory region 500.

The flash memories 9₀, 9₁, 9₂, and 9₃ of the respective memory groups 510 and 511 are connected to the data bus 509, and input/output of commands, statuses, addresses, and data is executed between the flash memories 9₀, 9₁, 9₂, and 9₃ and the respective controllers 502 and 503 or between the flash memories 9₀, 9₁, 9₂, and 9₃ and the DRAM 501 through the data bus 509.

In the interleaving operation, during an operation required for the flash memory (chip or MCP) 9₀ and 9₂ included in one memory group 510, an operation (or preparation for an operation) for the flash memory (chip or MCP) 9₁ and 9₃ included in the other memory group 511 is started.

For example, during a period that generation and application of a write voltage (or a read voltage) with respect to a selected word line in the memory cores 1₀ and 1₂ are executed with respect to the even-numbered flash memory chips 9₀ and 9₂, commands, data, and addresses are input or output with respect to I/O circuits 20₁ and 20₃ in the odd-numbered flash memories 9₁ and 9₃.

In the flash memories 9₀ and 9₂ belonging to the first memory group 510 and the flash memories 9₁ and 9₃ belonging to the second memory group 511, the parallel operation of the memories, e.g., the interleaving operation enables optimization of management/operation of the flash memories 9₀, 9₁, 9₂, and 9₃ in the memory system 200, a high-speed operation of the memory system 200, and avoidance of overlap of current peak generation timing.

As a result, the SSD (memory system) 50 including the flash memory 9 according to this embodiment can reduce the power consumption of the SSD 50 and improve operation characteristics of the SSD 50.

Like the SSD 50 including the flash memory 9 according to this embodiment, in relation to a reduction in power consumption of each flash memory (package or MCP) 9, a calorific value of the flash memory 9 is reduced. As a result, in the memory system 200 including the flash memories 9 according to this embodiment, the number of chips of the flash memories 9 that can perform the interleaving operation (the parallel operation) can be increased.

For example, if the power consumption of the flash memory 9 is reduced to half, a calorific value (an increase in temperature of the chip/memory package) of the flash memory 9 is reduced to half. In this case, the SSD 50 (and the memory card) using each flash memory 9 in this embodiment enable the chips of the flash memories 9 that double the number of flash memories in a conventional example to operate in parallel with the same calorific value as that in the conventional example or the same electric power as that in the conventional example.

When the operation of each of the flash memories 9₀, 9₁, 9₂, and 9₃ in the SSD 50 as the memory system 200 is controlled by the interleaving operation, it is preferable to supply the low drive voltage V_{CC2} (a voltage close to or substantially equal to the drive voltage V_{CCQ} of the I/O circuit 20) to the low-voltage drive circuit group 5 of the memory core 1. Further, when a high-speed operation of the I/O circuit (the interface) 20 is required, it is preferable to set the drive voltage V_{CCQ} supplied to the I/O circuit 20 to a low voltage (e.g., approximately 1.2 V to 1.5 V).

It is to be noted that, when the above-described memory card 40 includes the memory chips, this memory card can also perform the interleaving operation.

The SSD 50 as the memory system 200 according to this embodiment can achieve a reduction in power consumption, enhancement of operation performance, and improvement of storage density/storage capacity.

As described above, in the flash memory system according to this embodiment, the power consumption of the memory can be reduced, and deterioration of operation characteristics of the memory can be suppressed.

[Others]

In this embodiment, in accordance with the specifications of the memory system or the flash memory, a voltage having the same intensity as at least one of the drive voltage V_{CC1}, V_{CC2}, and V_{CCQ}, as the power supply voltage, may be directly supplied from the outside to the voltage regulation circuit or the each power supply line/terminal.

In this embodiment, although the NAND flash memory has been exemplified as the semiconductor memory, this embodiment can be applied to a flash memory other than the NAND flash memory, e.g., an NOR or AND flash memory.

In this embodiment, although the flash memory has been exemplified as the semiconductor memory, this embodiment can be applied to a memory such as an MRAM, a PCRAM, or a Resistive RAM (ReRAM) as long as the memory is configured in such a manner that a structure of a chip of a semiconductor memory has three or more power supply systems that are independent from each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a first semiconductor memory including: a memory core; an input/output circuit configured to input/output a signal; and first to third power supply terminals which are electrically separated from each other, the memory core including a memory cell array including memory cells; a first circuit configured to generate a voltage supplied to the memory cell array; and a second circuit configured to control an operation of the memory cell array, the first power supply terminal being connected to the first circuit, the second power supply terminal being connected to the input/output circuit, and the third power supply terminal being connected to the second circuit;
a control device which controls an operation of the first semiconductor memory;
a voltage control circuit to which a reference voltage and a first voltage higher than the reference voltage is input and which generates first to third drive voltages higher than the reference voltage from the first voltage; and
first to third power supply lines that are electrically separated from each other, the first power supply line being connected to the first power supply terminal, the second power supply line being connected to the second power supply terminal and the control device, and the third power supply line being connected to the third power supply terminal,
wherein the voltage control circuit supplies:
the first drive voltage to the first circuit through the first power supply terminal and the first power supply line,
the second drive voltage lower than the first drive voltage to the input/output circuit through the second power supply terminal and the second power supply line;
the third drive voltage to the second circuit through the third power supply terminal and the third power supply line; and
the second drive voltage to the control device through the second power supply line.

2. The memory system according to claim 1,
wherein the third drive voltage is equal to or lower than the first drive voltage and higher than the second drive voltage.

3. The memory system according to claim 1,
wherein the third drive voltage is lower than the first drive voltage and higher than the second drive voltage.

4. The memory system according to claim 1,
wherein the third drive voltage is substantially equal to the second drive voltage.

5. The memory system according to claim 1,
wherein the first drive voltage is substantially equal to the first voltage.

6. The memory system according to claim 1,
wherein the reference voltage is applied to the first circuit, the second circuit, and the input/output circuit through a fourth power supply line.

7. The memory system according to claim 1,
wherein the control devise comprises
a first interface circuit which controls input/output of a signal between the first semiconductor memory and the control device; and a second interface circuit which controls input/output of a signal between a host device, which requests input/output of data with respect to the first semiconductor memory, and the control device,
wherein the first and second interface circuits are connected to the second power supply line, and
the second drive voltage is applied to the first and second interface circuits.

8. The memory system according to claim 1, further comprising:
a second semiconductor memory which temporarily stores data that is input to or output from the first semiconductor memory and data that is used for controlling the first semiconductor memory,
wherein the second semiconductor memory is connected to the second power supply line, and the second drive voltage is applied to the second semiconductor memory.

9. The memory system according to claim 8,
wherein the first semiconductor memory is a flash memory, and the second semiconductor memory is a random access memory.

10. The memory system according to claim 1,
wherein the first circuit is a potential generation circuit including a charge pump.

11. The memory system according to claim 1,
wherein the second circuit is at least one selected from an internal control circuit, a buffer in a row/column control circuit, a decoder in the row/column control circuit, and a register.

12. The memory system according to claim 11,
wherein allowable characteristics of the second circuit are different from allowable characteristics of the input/output circuit.

13. The memory system according to claim 1,
wherein the voltage control circuit includes a direct current converter which generates the first to third drive voltages from the first voltage.

14. A control method of a memory system comprising:
inputting a reference voltage and a first voltage higher than the reference voltage to a voltage control circuit, the voltage control circuit being included in the memory system;
generating first to third drive voltages from the first voltage by the voltage control circuit, the second drive voltage being lower than the first drive voltage;
supplying the first drive voltage to a first circuit in a first semiconductor memory, supplying the second drive voltage to an input/output circuit in the first semiconductor memory, and supplying the third drive voltage to a second circuit in the first semiconductor memory, through power supply terminals being independent from each other, respectively, the first semiconductor memory being included in the memory system.

15. The control method of the memory system according to claim 14,
wherein the third drive voltage is equal to or lower than the first drive voltage and higher than the second drive voltage.

16. The control method of the memory system according to claim 14,
wherein the third drive voltage is substantially equal to the second drive voltage.

17. The control method of the memory system according to claim 14,
wherein the first drive voltage is substantially equal to the first voltage.

18. The control method of the memory system according to claim 14, further comprising:
supplying the second drive voltage to a control device which controls an operation of the first semiconductor memory, the control device being included in the memory system.

19. The control method of the memory system according to claim 14, further comprising:
supplying the second drive voltage to a second semiconductor memory, the second semiconductor memory being included in the memory system and temporally storing data that is input to or output from the first semiconductor memory and data that is used for controlling the first semiconductor memory.

20. The control method of the memory system according to claim 14,
wherein the first semiconductor memory is a flash memory,
the first circuit is a potential generation circuit including a charge pump, and
the second circuit is at least one selected from an internal control circuit, a buffer in a row/column control circuit, a decoder in the row/column control circuit, and a register.
